(19) United States
(12) Patent Application Publication
(10) Pub. No.: US 2014/0355635 A1
(43) Pub. Date: Dec. 4, 2014

(54) TWO DIMENSIONAL PHOTONIC CRYSTAL SURFACE EMITTING LASERS

(71) Applicant: ROHM CO., LTD., Kyoto (JP)

(72) Inventors: Seita IWAHASHI, Kyoto (JP); Dai ONISHI, Kyoto (JP); Eiji MIYAI, Kyoto (JP); Wataru KUNISHI, Kyoto (JP)

(73) Assignee: ROHM CO., LTD., Kyoto (JP)

(21) Appl. No.: 14/294,411

(22) Filed: Jun. 3, 2014

(30) Foreign Application Priority Data
Jun. 3, 2013 (JP) 2013-117209

(51) Int. Cl. H01S 5/10; H01S 5/18

(52) U.S. Cl. CPC H01S 5/105; H01S 5/18
USPC 372/45.01

(57) ABSTRACT

The 2D-PC SEL includes: a PC layer; and a lattice point for forming resonant-state arranged in the PC layer, and configured so that a light wave at a band edge in photonic band structure in the PC layer is diffracted in a plane of the PC layer, and is diffracted in a direction normal to the surface of the PC layer. The lattice point for forming resonant-state has two types of lattice points including a first lattice point and a second lattice point, and the shapes of the adjacent first lattice point and second lattice point are different from each other.

### CROSS REFERENCE TO RELATED APPLICATIONS

This application is based upon and claims the benefit of priority from prior Japanese Patent Application No. P2013-117209 filed on Jun. 3, 2013, the entire contents of which are incorporated herein by reference.

### FIELD

Embodiments described herein relate to two dimensional photonic crystal (2D-PC) surface emitting lasers (SEL).

### BACKGROUND

Conventional photonic crystal (PC) laser diodes (LD) have used an oscillation at a Γ-point (gamma-point) band edge of photonic band structure.

The Γ-point (gamma-point) oscillation has both of a function for forming a resonant state for an oscillation of periodic structure in the PC, and a function for extracting the light as outputs, to a PC layer by diffracting the light in a direction normal to the surface.

### SUMMARY

The inventors of the present application found out theoretically and also experimentally proved that laser beams can be emitted vertically using one type or two types of hole shape by applying periodic perturbation to specific lattice points, while continuing periodic structure of lattice points for forming resonant condition, in non-radiative resonator structure, e.g. an M-point resonator.

The embodiments described herein provide a 2D-PC SEL which can vertically emit laser beams with simplified structure in non-radiative resonator structure, e.g. an M-point resonator.

According to one aspect of the embodiments, there is provided a 2D-PC SEL comprising: a PC layer; and a lattice point for forming resonant-state arranged in the PC layer, the lattice point for forming resonant-state configured so that a light wave at a band edge in photonic band structure in the PC layer is diffracted in a plane of the PC layer, and is diffracted in a direction normal to the surface of the PC layer, wherein the lattice point for forming resonant-state has two types of lattice points including a first lattice point and a second lattice point, and the adjacent first lattice point and second lattice point are different from each other.

According to another aspect of the embodiments, there is provided a 2D-PC SEL comprising: a PC layer; a lattice point for forming resonant-state periodically arranged in the PC layer, the lattice point for forming resonant-state configured so that a light wave at a band edge of photonic band structure in the PC layer is diffracted in a plane of the PC layer; and a perturbation lattice point periodically arranged in the PC layer, the perturbation lattice point configured so that the light wave at the band edge of the photonic band structure in the PC layer is diffracted in the plane of the PC layer, and is diffracted in a direction normal to the surface of the PC layer, wherein perturbation for diffracting the light wave in the direction normal to the surface of the PC layer is applied to a part of the lattice point for forming resonant-state, and thereby the perturbation lattice point is formed.

According to still another aspect of the embodiments, there is provided a 2D-PC SEL comprising: a PC layer; a resonator region periodically arranged in the PC layer, the resonator region configured so that a light wave at a band edge of photonic band structure in the PC layer is diffracted in a plane of the PC layer; and a perturbation region periodically arranged in the PC layer, the perturbation region configured so that the light wave at the band edge of the photonic band structure in the PC layer is diffracted in the plane of the PC layer, and is diffracted in a direction normal to the surface of the PC layer, wherein the perturbation region has two types of lattice points including a first lattice point and a second lattice point, and the adjacent first lattice point and second lattice point are different from each other.

According to the embodiments, there can be provided the 2D-PC SEL which can vertically emit laser beams with simplified structure in the non-radiative resonator structure, e.g. the M-point resonator.

### BRIEF DESCRIPTION OF DRAWINGS

FIG. 1 is a schematic bird's-eye view structure diagram showing a 2D-PC SEL according to a first embodiment.

FIG. 2A shows real space of a rectangular lattice of a 2D-PC layer applied to the 2D-PC SEL according to the first embodiment.

FIG. 2B shows wave number space corresponding to FIG. 2A.

FIG. 3A is an operational principle diagram of surface light emission of the 2D-PC SEL as an example in the case where the 2D-PC layer has rectangular lattice points, and is in particular an explanatory diagram in the real space of the in-plane resonant state of the rectangular lattice in the 2D-PC layer.

FIG. 3B is an explanatory diagram in the wave number space corresponding to FIG. 3A.

FIG. 4A is an explanatory diagram in the wave number space kₓ−k_{y} of a diffraction operation in the upward direction (z axial direction), in the in-plane resonant state corresponding to FIG. 3.

FIG. 4B is an explanatory diagram in the wave number space k_{z}−k_{y} corresponding to FIG. 4A.

FIG. 5A shows a real space example of the lattice points for forming resonant-state (resonant-state-forming lattice points) (rectangular lattice) in the 2D-PC layer, in the 2D-PC SEL according to comparative example 1.

FIG. 5B shows a real space example of lattice points for light extraction in the 2D-PC layer.

FIG. 5C shows a real space example in which the lattice points for forming resonant-state (resonant-state-forming lattice points) and the lattice point for light extraction are combined with each other.

FIG. 5D shows wave number space corresponding to FIG. 5A.

FIG. 5E shows wave number space corresponding to FIG. 5C.

FIG. 6A shows a real space example of the lattice points for forming resonant-state (resonant-state-forming lattice points) (rectangular lattice) in the 2D-PC layer, in the 2D-PC SEL according to comparative example 2.

FIG. 6B shows a conceptual diagram for explaining an aspect that the perturbation of the sine wave function is applied in the y-axial direction to the lattice point for forming resonant-state (rectangular lattice) in the 2D-PC layer.

FIG. 6C shows a conceptual diagram for explaining an aspect that hole-shape (hole-diameter) modulation is applied in the y-axial direction to the lattice point for forming resonant-state (rectangular lattice) in the 2D-PC layer.

FIG. 7A shows wave number space corresponding to FIG. 6A.

FIG. 7B shows wave number space corresponding to FIG. 6B.

FIG. 8A shows a real space example of the lattice points for forming resonant-state (resonant-state-forming lattice points) (rectangular lattice) in the 2D-PC layer, in the 2D-PC SEL according to the first embodiment.

FIG. 8B is a conceptual diagram for illustrating an aspect that perturbation of a sine wave function is applied in y axial direction to the lattice points for forming resonant-state (resonant-state-forming lattice points) (rectangular lattice) in the 2D-PC layer, in the 2D-PC SEL according to the first embodiment.

FIG. 9A shows an example of rectangle lattice arrangement of the lattice point for forming resonant-state in the 2D-PC layer, in the 2D-PC SEL according to the first embodiment, and shows in particular an example where adjacent lattice points have shapes different from each other.

FIG. 9B shows an example of rectangle lattice arrangement of the lattice point for forming resonant-state in the 2D-PC layer, in the 2D-PC SEL according to the first embodiment, and shows in particular an example where the adjacent lattice points have the same shape, but the arrangement directions are different from each other.

FIG. 10 shows an example of rectangle lattice arrangement of the lattice point for forming resonant-state in the 2D-PC layer, in the 2D-PC SEL according to the first embodiment, and shows in particular another example where the adjacent lattice points have the same shape, but the arrangement directions are different from each other.

FIG. 11A shows an example of rectangle lattice arrangement of the lattice point for forming resonant-state in the 2D-PC layer, in the 2D-PC SEL according to the first embodiment, and shows in particular still another example where the adjacent lattice points have the same shape, but the arrangement directions are different from each other.

FIG. 11B shows an example of rectangle lattice arrangement of the lattice point for forming resonant-state in the 2D-PC layer, in the 2D-PC SEL according to the first embodiment, and shows in particular yet another example where the adjacent lattice points have the same shape, but the arrangement directions are different from each other.

FIG. 12 is a schematic plane configuration diagram of lattice points for forming resonant-state 12A and lattice points for coupler 12C (example of square lattice arrangement) in a 2D-PC layer applied to an M-point oscillation, in a 2D-PC SEL according to a comparative example 3.

FIG. 13A shows an example of square lattice arrangement of the lattice point for forming resonant-state in the 2D-PC layer, in the 2D-PC SEL according to the first embodiment, and shows in particular an example where adjacent lattice points have shapes different from each other.

FIG. 13B shows an explanatory diagram of FIG. 13A.

FIG. 14 shows an example of square lattice arrangement of the lattice point for forming resonant-state in the 2D-PC layer, in the 2D-PC SEL according to the first embodiment, and shows in particular another example where adjacent lattice points have shapes different from each other.

FIG. 15A shows an example of square lattice arrangement of the lattice point for forming resonant-state in the 2D-PC layer, in the 2D-PC SEL according to the first embodiment, and shows in particular an example where the adjacent lattice points have sizes different from each other.

FIG. 15B shows an example of square lattice arrangement of the lattice point for forming resonant-state in the 2D-PC layer, in the 2D-PC SEL according to the first embodiment, and shows in particular another example where the adjacent lattice points have sizes different from each other.

FIG. 16A shows an example of square lattice arrangement of the lattice point for forming resonant-state in the 2D-PC layer, in the 2D-PC SEL according to the first embodiment, and shows in particular still another example where adjacent lattice points have shapes different from each other.

FIG. 16B shows an example of square lattice arrangement of the lattice point for forming resonant-state in the 2D-PC layer, in the 2D-PC SEL according to the first embodiment, and shows in particular yet another example where adjacent lattice points have shapes different from each other.

FIG. 17 shows a schematic explanatory diagram of a Far Field Pattern (FFP) of the lattice point for forming resonant-state (square lattice M-point) in the 2D-PC layer, in the 2D-PC SEL according to the first embodiment.

FIG. 18A is a schematic plane configuration diagram of lattice points for forming resonant-state in a 2D-PC layer applied to the Γ-point (gamma-point) oscillation (square lattice arrangement example where adjacent lattice points have shapes different from each other), in a 2D-PC SEL according to a second embodiment.

FIG. 18B shows a diagram of 2D-PC band structure corresponding to FIG. 18A.

FIG. 19A is a schematic plane configuration diagram (example of square lattice arrangement) of the lattice points for forming resonant-state in the 2D-PC layer applied to the M-point oscillation, and the perturbation lattice points to which the perturbations, e.g. refractive index modulation, hole-shape (hole-diameter) modulation, hole-depth modulation, are applied thereto, in the 2D-PC SEL according to the second embodiment.

FIG. 19B shows a diagram of the 2D-PC band structure corresponding to FIG. 19A.

FIG. 20A is a schematic plane configuration diagram (example of square lattice arrangement) of the lattice points for forming resonant-state and the perturbation lattice points in the 2D-PC layer applied to the X-point oscillation, in the 2D-PC SEL according to the second embodiment.

FIG. 20B shows a diagram of the 2D-PC band structure corresponding to FIG. 20A.

FIG. 21A is a schematic plane configuration diagram (example of triangular lattice arrangement) of the lattice points for forming resonant-state and the perturbation lattice points in the 2D-PC layer applied to the X-point oscillation, in the 2D-PC SEL according to the second embodiment.

FIG. 21B shows a diagram of the 2D-PC band structure corresponding to FIG. 21A.

FIG. 22A is a schematic plane configuration diagram (example of triangular lattice arrangement) of the lattice points for forming resonant-state and the perturbation lattice points in the 2D-PC layer applied to the J-point oscillation, in the 2D-PC SEL according to the second embodiment.

FIG. 22B shows a diagram of the 2D-PC band structure corresponding to FIG. 22A.

FIG. 23A is a schematic plane configuration diagram (example of rectangle lattice arrangement: a₁>a₂) of the lattice points for forming resonant-state and the perturbation lattice points in the 2D-PC layer applied to the X-point oscillation, in the 2D-PC SEL according to the second embodiment.

FIG. 23B shows a diagram of the 2D-PC band structure corresponding to FIG. 23A.

FIG. 24A is a schematic plane configuration diagram (example of rhombic lattice arrangement) of the lattice points for forming resonant-state and the perturbation lattice points in the 2D-PC layer applied to the X-point oscillation, in the 2D-PC SEL according to the second embodiment.

FIG. 24B shows a diagram of the 2D-PC band structure corresponding to FIG. 24A.

FIG. 25A is a schematic plane configuration diagram (example of rectangle lattice arrangement: a₁<a₂) of the lattice points for forming resonant-state and the perturbation lattice points in the 2D-PC layer applied to the X-point oscillation, in the 2D-PC SEL according to the second embodiment.

FIG. 25B shows a diagram of the 2D-PC band structure corresponding to FIG. 25A.

FIG. 26A is a schematic plane configuration diagram (example of rhombic lattice arrangement) of the lattice points for forming resonant-state and the perturbation lattice points in the 2D-PC layer applied to the X-point oscillation, in the 2D-PC SEL according to the second embodiment.

FIG. 26B shows a diagram of the 2D-PC band structure corresponding to FIG. 26A.

FIG. 27A is a diagram showing a relationship between a width, a beam spread angle θ, and a beam spread region 30 of a perturbation region PP₁, in the 2D-PC SEL according to the second embodiment, and showing in particular an example of the width A₁, the beam spread angle θₐ, and the beam spread region 30₁ of the perturbation region PP1.

FIG. 27B shows an example of the width A₂, the beam spread angle θ_{b}, and the beam spread region 30₂ of the perturbation region PP₂, in the 2D-PC SEL according to the second embodiment.

FIG. 27C shows an example of the width A₃, the beam spread angle θ_{C}, and the beam spread region 30₃ of the perturbation region PP₃, in the 2D-PC SEL according to the second embodiment.

FIG. 28A is a diagram showing a size relationship between resonator regions RP corresponding to FIGS. 27A, 27B and 27C, in the 2D-PC SEL according to the second embodiment.

FIG. 28B is a diagram showing a size relationship between the beam spread angles θ corresponding to FIGS. 27A, 27B and 27C, in the 2D-PC SEL according to the second embodiment.

FIG. 29A is a diagram showing a size relationship between resonator regions RP in the 2D-PC layer applied to the Γ-point (gamma-point) oscillation, and is in particular an example of RP₁, in the 2D-PC SEL according to the comparative example 4.

FIG. 29B is a diagram showing a size relationship between resonator regions RP in the 2D-PC layer applied to the Γ-point (gamma-point) oscillation, and is in particular an example of RP₂, in the 2D-PC SEL according to the comparative example 4.

FIG. 29C is a diagram showing a size relationship between resonator regions RP in the 2D-PC layer applied to the Γ-point (gamma-point) oscillation, and is in particular an example of RP₃, in the 2D-PC SEL according to the comparative example 4.

FIG. 30A is a diagram showing a size relationship between the resonator regions RP and the perturbation region PP in the 2D-PC layer applied to the X-point oscillation, and is in particular an example of RP₁ and PP₁, in the 2D-PC SEL according to the second embodiment.

FIG. 30B is a diagram showing a size relationship between the resonator regions RP and the perturbation region PP in the 2D-PC layer applied to the X-point oscillation, and is in particular an example of RP₂ and PP₂, in the 2D-PC SEL according to the second embodiment.

FIG. 30C is a diagram showing a size relationship between the resonator regions RP and the perturbation region PP in the 2D-PC layer applied to the X-point oscillation, and is in particular an example of RP₃ and PP₃, in the 2D-PC SEL according to the second embodiment.

FIG. 31 shows an example of arrangement of the lattice points for forming resonant-state 12A and the perturbation lattice point 12P in the resonator region RP and in the perturbation region PP in the 2D-PC layer applied to the X-point oscillation, in the 2D-PC SEL according to the second embodiment.

FIG. 32A shows a Near Field Pattern (NFP) in the case where the size of the resonator region RP and the size of the perturbation region PP in the 2D-PC layer applied to the X-point oscillation are nearly equal to each other, in a 2D-PC SEL according to the modified example of the second embodiment.

FIG. 32B shows a schematic diagram of a beam spread region from the perturbation region PP in the case where the size of the resonator region RP and the size of the perturbation region PP in the 2D-PC layer applied to the X-point oscillation are nearly equal to each other, in the 2D-PC SEL according to the modified example of the second embodiment.

FIG. 32C shows a real space example in the case of applying the perturbation in x-axial direction to the lattice point for forming resonant-state in the resonator region RP and the perturbation region PP corresponding to FIG. 32A.

FIG. 33A shows an NFP in the case where the size of the resonator region RP and the size of the perturbation region PP in the 2D-PC layer applied to the X-point oscillation differ from each other, in the 2D-PC SEL according to the modified example of the second embodiment.

FIG. 33B shows a schematic diagram of the beam spread region from the perturbation region PP in the case where the size of the resonator region RP and the size of the perturbation region PP in the 2D-PC layer applied to the X-point oscillation differ from each other, in the 2D-PC SEL according to the modified example of the second embodiment.

FIG. 33C shows a real space example in the case of applying the perturbation in x-axial direction to the lattice point for forming resonant-state in the perturbation region PP corresponding to FIG. 33A.

FIG. 34A shows an NFP in the case where a relatively large circular perturbation region PP is arranged on the resonator region RP in the 2D-PC layer applied to the M-point oscillation, in the 2D-PC SEL according to the modified example of the second embodiment.

FIG. 34B shows the FFP corresponding to FIG. 34A.

FIG. 35A shows an NFP in the case where a relatively small circular perturbation region PP is arranged on the resonator region RP, in the 2D-PC SEL according to the modified example of the second embodiment.

FIG. 35B shows the FFP corresponding to FIG. 35A.

FIG. 36A shows an NFP in the case where a relatively micro circular perturbation region PP is arranged on the resonator region RP in the 2D-PC layer applied to the M-point oscillation, in the 2D-PC SEL according to the modified example of the second embodiment.

FIG. 36B shows the FFP corresponding to FIG. 36A.

FIG. 37A shows an NFP in the case where a relatively large ellipse perturbation region PP is arranged on the resonator region RP in the 2D-PC layer applied to the M-point oscillation, in the 2D-PC SEL according to the modified example of the second embodiment.

FIG. 37B shows rhe FFP corresponding to FIG. 37A.

FIG. 38A shows an NFP in the case where a plurality of relatively small circular perturbation regions PP are arranged on the resonator region RP in the 2D-PC layer applied to the M-point oscillation, in the 2D-PC SEL according to the modified example of the second embodiment.

FIG. 38B shows the FFP corresponding to FIG. 38A.

FIG. 39A shows an NFP in the case where two ellipse perturbation regions PP perpendicularly intersecting with each other are arranged on the resonator region RP in the 2D-PC layer applied to the M-point oscillation, in the 2D-PC SEL according to the modified example of the second embodiment.

FIG. 39B shows the FFP corresponding to FIG. 39A.

FIG. 40A shows an NFP in the case where three ellipse perturbation regions PP intersecting at 60 degrees with each other are arranged on the resonator region RP in the 2D-PC layer applied to the M-point oscillation, in the 2D-PC SEL according to the modified example of the second embodiment.

FIG. 40B shows the FFP corresponding to FIG. 40A.

FIG. 41A shows an NFP in the case where two ellipse perturbation regions PP intersecting at 120 degrees with each other are arranged on the resonator region RP in the 2D-PC layer applied to the M-point oscillation, in the 2D-PC SEL according to the modified example of the second embodiment.

FIG. 41B shows the FFP corresponding to FIG. 41A.

FIG. 42A shows an NFP in the case where five ellipse perturbation regions PP intersecting at 72 degrees with each other are arranged on the resonator region RP in the 2D-PC layer applied to the M-point oscillation, in the 2D-PC SEL according to the modified example of the second embodiment.

FIG. 42B shows the FFP corresponding to FIG. 42A.

FIG. 43 shows a structural example of two-dimensional cell array for achieving high power output, in a 2D-PC SEL according to a third embodiment.

FIG. 44A shows a two-dimensional cell arrayed structural example that a basic pattern T₀ of the lattice point for forming resonant-state is arranged in a 2D-PC layer on a first cladding layer, and perturbation patterns T₁, T₂, T₃, T₄ of rectangular-shaped perturbation regions PP1, PP2, PP3, PP4 are arranged in the 2D-PC layer, in the 2D-PC SEL according to the third embodiment.

FIG. 44B shows a two-dimensional cell arrayed structural example that a basic pattern T₀ of the lattice point for forming resonant-state is arranged in the 2D-PC layer on the first cladding layer, and perturbation patterns T₁, T₂, T₃, T₄ of hexagon-shaped perturbation regions PP1, PP2, PP3, PP4 are arranged in the 2D-PC layer.

FIG. 45 shows a two-dimensional cell arrayed structural example of arranging the configuration shown in FIG. 44B on a plurality of chips on the same substrate, in the 2D-PC SEL according to the third embodiment.

FIG. 46 shows a two-dimensional cell arrayed structural example of arranging a plurality of chips, of which the FFP differs from each other, on the same substrate, in the 2D-PC SEL according to the third embodiment.

### DESCRIPTION OF EMBODIMENTS

Next, certain embodiments will be described with reference to drawings. In the description of the following drawings, the identical or similar reference numeral is attached to the identical or similar part. However, it should be noted that the drawings are schematic and the relation between thickness and the plane size and the ratio of the thickness of each component part differs from an actual thing. Therefore, detailed thickness and size should be determined in consideration of the following explanation. Of course, the part from which the relation and ratio of a mutual size differ also in mutually drawings is included.

Moreover, the embodiments described hereinafter exemplify the apparatus and method for materializing the technical idea; and the embodiments does not specify the material, shape, structure, placement, etc. of each component part as the following. The embodiments may be changed without departing from the spirit or scope of claims.

### First Embodiment

### (Element Structure)

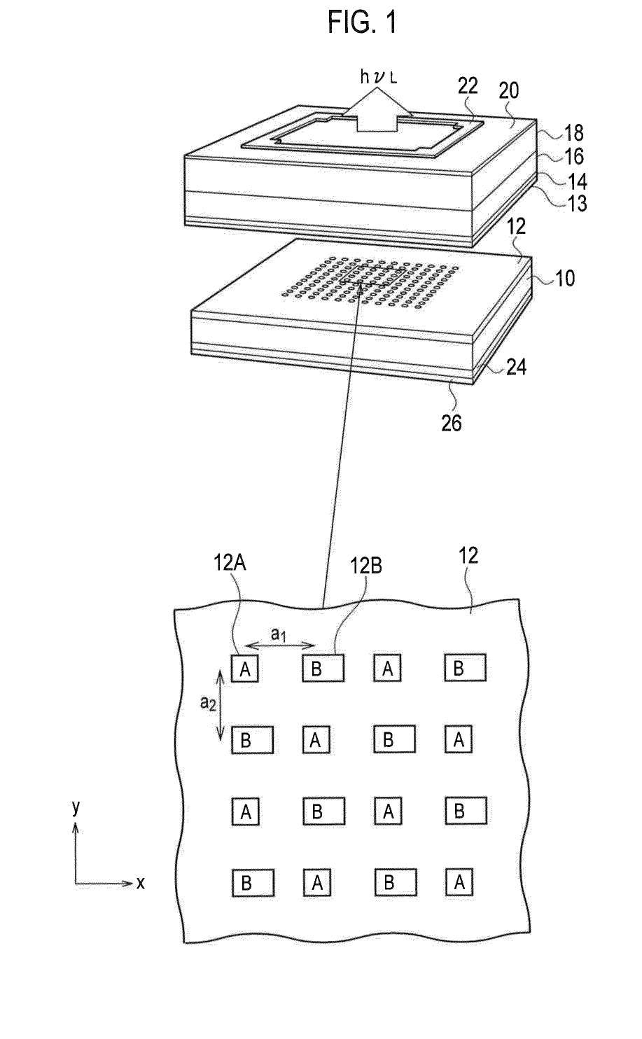

As shown in FIG. 1, a schematic bird's-eye view structure of a 2D-PC SEL according to the first embodiment includes: a PC layer 12; and lattice points for forming resonant-state (resonant-state-forming lattice point) arranged in the PC layer 12, the lattice points for forming resonant-state configured so that a light wave at a band edge in photonic band structure in the PC layer 12 is diffracted in a plane of the PC layer 12 and is diffracted in a direction normal to the surface of the PC layer 12, wherein the lattice points for forming resonant-state has two types of lattice points including a first lattice point 12A and a second lattice point 12B, and the adjacent first lattice point 12A and second lattice point 12B are different from each other.

Moreover, the shape of the first lattice point 12A and the shape of the second lattice point 12B may be different from each other.

Moreover, the size of the first lattice point 12A and the size of the second lattice point 12B may be different from each other.

Moreover, the hole depth of the first lattice point 12A and the hole depth of the second lattice point 12B may be different from each other.

Moreover, the refractive index of the first lattice point 12A and the refractive index of the second lattice point 12B may be different from each other.

Moreover, the shape of the first lattice point 12A and the shape of the second lattice point 12B may be the same, but the arrangement direction of the first lattice point 12A and the arrangement direction the second lattice point 12B may be different from each other.

Moreover, the lattice points for forming resonant-state 12A, 12B are arranged in anyone selected from the group consisting of a square lattice, a rectangular lattice (a face-centered rectangle lattice), and a triangular lattice.

Moreover, the lattice points for forming resonant-state 12A, 12B may be arranged in a square lattice or a rectangular lattice, and thereby can diffract the light wave at a Γ point (gamma-point), an X point, or an M point in the photonic band structure of the PC layer 12 in the direction normal to the surface of the PC layer 12.

Moreover, the lattice points for forming resonant-state 12A, 12B may be arranged in a face-centered rectangle lattice (rhombic lattice) or a triangular lattice, and thereby can diffract the light wave at a Γ point (gamma-point), an X point, or an J point in the photonic band structure of the PC layer 12 in the direction normal to the surface of the PC layer 12.

Moreover, the lattice points for forming resonant-state 12A, 12B may be provided with any one of a polygonal shape, a circular shape, an ellipse shape, or an oval shape. The polygonal shape includes a triangle, a square, a four-square, a rectangle, etc.

In the example shown in FIG. 1, the lattice points for forming resonant-state 12A, 12B are adjacent to each other, and are respectively arranged in rectangular lattices, and respectively have shapes different from each other. The lattice constant of the rectangular lattice is expressed with (a₁, a₂). The hole shape of the lattice point for forming resonant-state 12A is a square, and the hole shape of the lattice point for forming resonant-state 12B is a rectangle, as shown in FIG. 1. The lattice points for forming resonant-state 12A and 12B diffract light waves at an M-point band edge in the photonic band structure of 2D-PC layer 12.

As shown in FIG. 1, the 2D-PC SEL according to the first embodiment includes: a substrate 24; a first cladding layer 10 disposed on the substrate 24; a second cladding layer 16 disposed on the first cladding layer 10; and an active layer 14 inserted between the first cladding layer 10 and the second cladding layer 16. In this case, the first cladding layer 10 may be formed of a p type semiconductor layer, and the second cladding layer 16 may be formed of an n type semiconductor layer. The electrical conductivity of the semiconductor layer may be reverse to each other.

As shown in FIG. 1, the 2D-PC SEL according to the first embodiment comprises: a contact layer 18 disposed on the second cladding layer 16; a window layer 20 disposed on a surface light emission region on the contact layer 18, and configured to extract a laser beam; a window-like upper electrode 22 disposed on the window layer 20; and a lower electrode 26 disposed on a back side surface of the substrate 24.

As shown in FIG. 1, the PC layer 12 may be inserted between the first cladding layer 10 and the second cladding layer 16 so as to be adjacent to the active layer 14 in a direction normal to the surface of the active layer 14. In this case, the active layer 14 may be formed of a Multi-Quantum Well (MQW) layer, for example.

Moreover, the PC layer 12 may be inserted between the first cladding layer 10 and the active layer 14, as shown in FIG. 1.

Moreover, as shown in FIG. 1, a carrier blocking layer 13 is inserted between the active layer 14 and the PC layer 12 so that carriers may be effectively acquired in the active layer 14 composed of the MQW layer, and a carrier injection from the active layer 14 to the PC layer 12 may be blocked.

Moreover, the PC layer 12 may be inserted between the second cladding layer 16 and the active layer 14.

As materials of the 2D-PC SEL according to the first embodiment, the following materials are applicable, for example. That is, for example, GaInAsP/InP based materials are applicable in the case of wavelengths of 1.3 μm to 1.5 μm; InGaAs/GaAs based materials are applicable in the case of an infrared light with a wavelength of 900 nm; GaAlAs/GaAs based or GaInNAs/GaAs based materials are applicable in the case of an infrared light/near-infrared light with wavelengths of 800 to 900 nm; GaAlInAs/InP based materials are applicable in the case of wavelengths of 1.3 μm to 1.67 μm; AlGaInP/GaAs based materials are applicable in the case of a wavelength of 0.65 μm; and GaInN/GaN based materials are applicable in the case of a blue light.

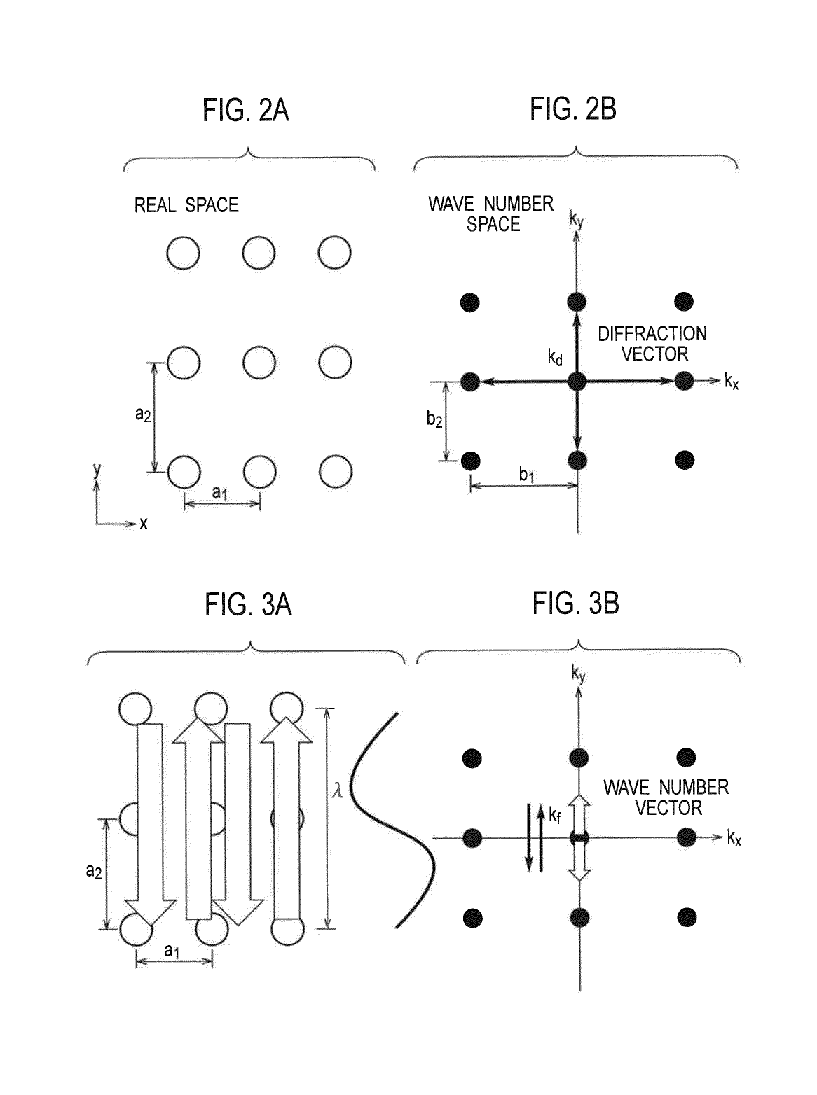

FIG. 2A shows the in-plane resonant mode of the 2D-PC layer 12 in the 2D-PC SEL according to the first embodiment, and FIG. 2B shows the wave number space corresponding to the Fourier transform of the real space of FIG. 2A. The lattice constant of the rectangular lattice is expressed by (a₁, a₂) as shown in FIG. 2A, and the reciprocal lattice constant is expressed by (b₁, b₂) as shown in FIG. 2B. The diffraction vector k_{d}↑ in the reciprocal lattice points is expressed as shown in FIG. 2B.

### (Principle of Surface Light Emission)

The principle of the surface light emission of the 2D-PC SEL will now be explained as an example in the case where the 2D-PC layer 12 has the lattice point of rectangular lattice.

In the 2D-PC SEL, FIG. 3A shows an explanatory diagram in the real space of the in-plane resonant state of the rectangular lattice in the 2D-PC layer 12, and FIG. 3B shows an explanatory diagram in the wave number space corresponding to FIG. 3A. In this case, the length of one side a₂ of the rectangular lattice is equal to ½ the wavelengths λ in the medium, in the example shown in FIG. 3A. In the in-plane resonant state shown in FIG. 3A, the wave number vector k_{f}↑ is expressed as shown in FIG. 3B.

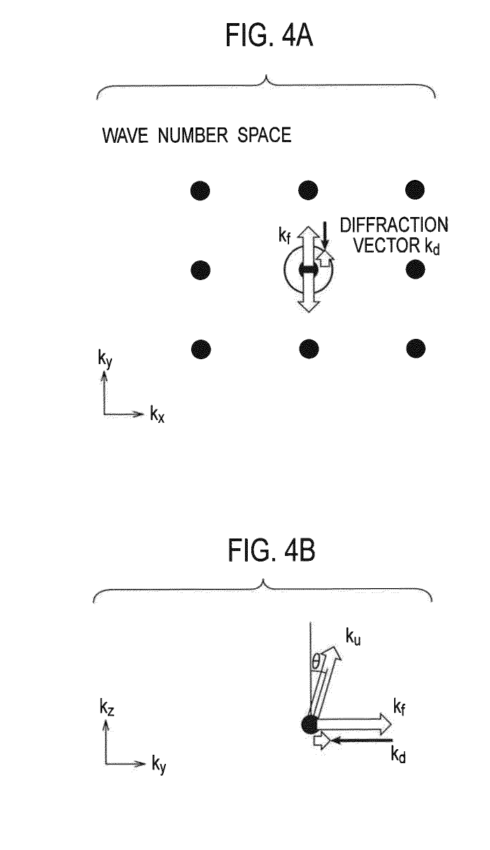

In the in-plane resonant state corresponding to FIG. 3, FIG. 4A shows an explanatory diagram in wave number space kₓ−k_{y} of a diffraction operation in an upward direction (z axial direction), and FIG. 4B shows an explanatory diagram in the wave number space k_{z}−k_{y} corresponding to FIG. 4A. The wave number vector kf↑ and the diffraction vector k_{d}↑ have difference |k_{f}−k_{d}| in the wave number space kₓ−k_{y} as shown in FIG. 4A, and the surface emission-type laser beam can be emitted on the wave number space k_{y}−k_{z} plane in a vector kᵤ↑ direction to which only an emitting angle θ inclined from the z axis, corresponding to the above-mentioned difference.

### Comparative Example 1

### Introduction of Coupler

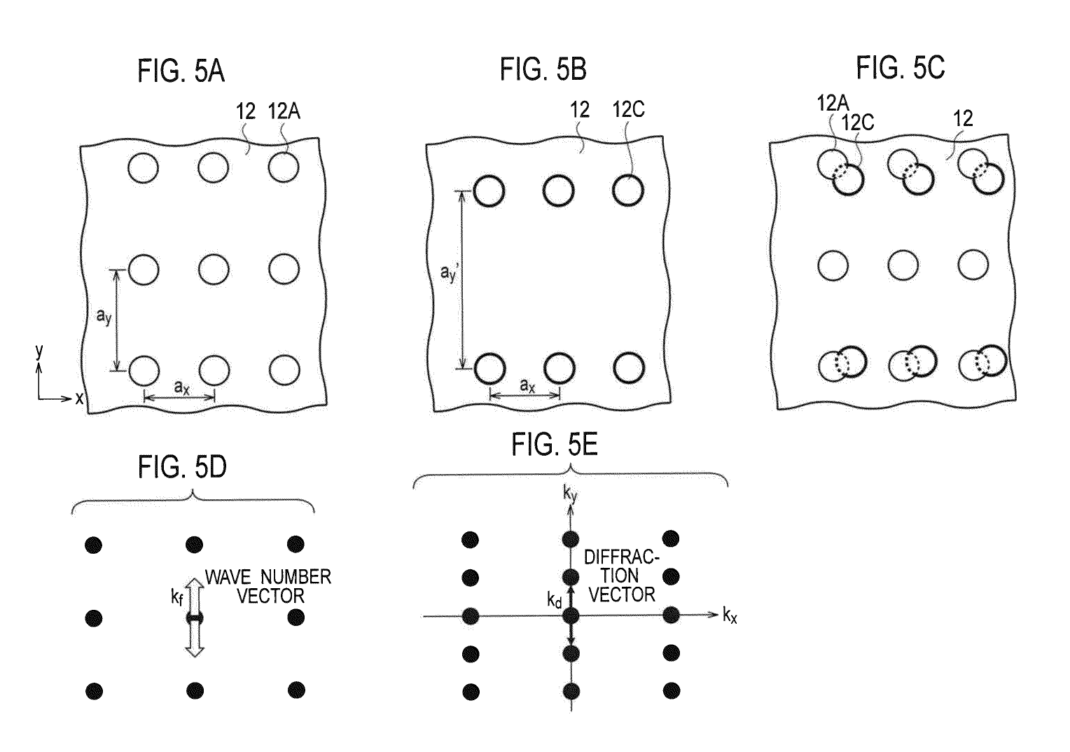

FIG. 5A shows a real space example of a lattice points for forming resonant-state in a 2D-PC layer, in a 2D-PC SEL according to a comparative example 1. FIG. 5B shows an real space example of the lattice point for light extraction 12C in the 2D-PC layer 12. Furthermore, FIG. 5C shows a real space example in which the lattice point for forming resonant-state 12A and the lattice point for light extraction 12C in the 2D-PC layer 12 are combined with each other.

Moreover, FIG. 5D shows the wave number space corresponding to FIG. 5A, and FIG. 5E shows the wave number space corresponding to FIG. 5C.

The lattice point for light extraction 12C is arranged in the same plane as the lattice point for forming resonant-state 12A and, and has periodic structure different from the fundamental structure of the lattice point for forming resonant-state 12A.

The dielectric constant ∈_{0.a}(r↑) in which the lattice point for forming resonant-state 12A and the lattice point for light extraction 12C are combined with each other is expressed by the following equation:

∈(r↑)=∈_{0.a}(r↑)+∈_{1.a′}(r↑) (1)

where ∈_{0.a}(r↑) is the dielectric constant of the lattice point for forming resonant-state 12A in the 2D-PC layer 12, and ∈_{1.a′}(r↑) is the dielectric constant of the lattice point for light extraction 12C.

Since the dielectric constant ∈(r↑) has periodic structure, the dielectric constant ∈(r↑) is expressed by the following equation:

∈ₐ(r↑)=∈ₐ(r↑+a↑) (2)

where |a↑| expresses the period related to the lattice.

In the comparative example 1, since the lattice point for forming resonant-state 12A and the lattice points for light extraction 12C, e.g. the X-point resonator, are used as different lattices, the lattice point for light extraction 12C significantly affects the resonant-state form. For example, unnecessary dispersion, a resonant mode which is not intended, etc. may occur by introducing the lattice point for light extraction 12C. Since two lattice points, the lattice point for forming resonant-state 12A and the lattice point for light extraction 12C, are compounded, the structure is complicated in the comparative example 1.

### Comparative Example 2

### Introduction of Perturbation

Accordingly, in the 2D-PC SEL according to a comparative example 2, the perturbation is applied to the lattice point for forming resonant-state 12A as a method of extracting light without using the lattice point for light extraction 12C. There is clearly little influence on the resonant-state form by introducing the perturbation, compared with structure of the comparative example 1 where newly superposes an alternative lattice.

The term “perturbation” used therein means that modulation is applied to the PC layer 12 which forms periodic structure in the lattice point for forming resonant-state 12A.

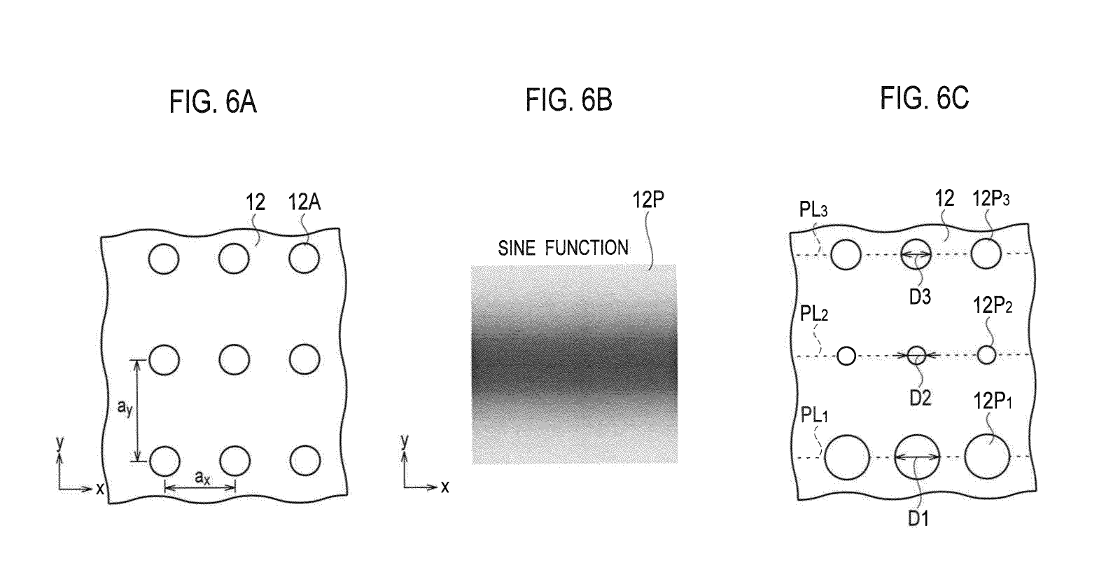

FIG. 6A shows a real space example of a lattice points for forming resonant-state in the 2D-PC layer, in the 2D-PC SEL according to a comparative example 2. FIG. 6B shows a conceptual diagram for explaining an aspect that the perturbation of the sine wave function is applied in the y-axial direction to the lattice point for forming resonant-state (rectangular lattice) 12A in the 2D-PC layer 12. Moreover, FIG. 6C shows a conceptual diagram for explaining an aspect that the perturbation of the hole-shape (hole-diameter) modulation of the sine wave function is applied in the y-axial direction to the lattice point for forming resonant-state (rectangular lattice). In FIG. 6C, the perturbations of the periodic hole-shaped (hole-size d) modulation of the sine wave function are applied in the vertical direction to the arrangement lines PL₁, PL₂, PL₃, . . . . For example, the perturbation lattice point 12P₁ to which the perturbation of the hole diameter D1 is applied is arranged on arrangement line PL₁. Similarly, the perturbation lattice point 12P₂ to which the perturbation of the hole diameter D2 is applied is arranged on the arrangement line PL₂, and the perturbation lattice point 12P₃ to which the perturbation of the hole diameter D3 is applied is arranged on the arrangement line PL₃.

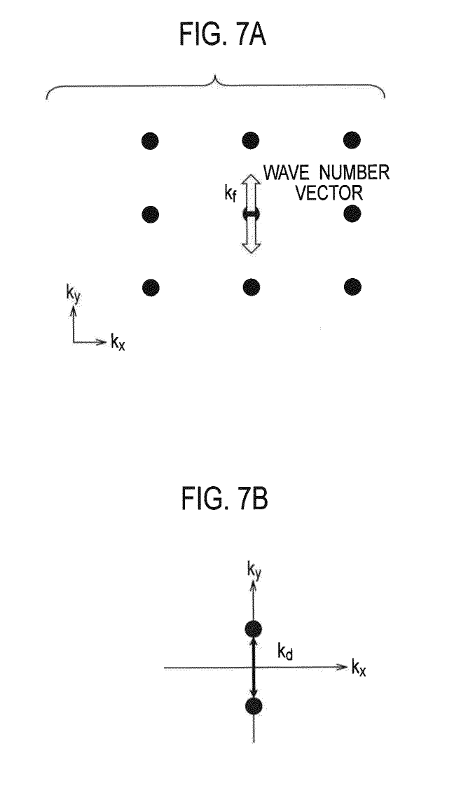

Moreover, the wave number space corresponding to the Fourier transform of the real space in FIG. 6A is expressed as shown in FIG. 7A, and the wave number space corresponding to the Fourier transform of the real space in FIG. 6B is expressed as shown in FIG. 7B. The wave number vector k_{f}↑ and the diffraction vector k_{d}↑ are as shown in FIGS. 7A and 7B.

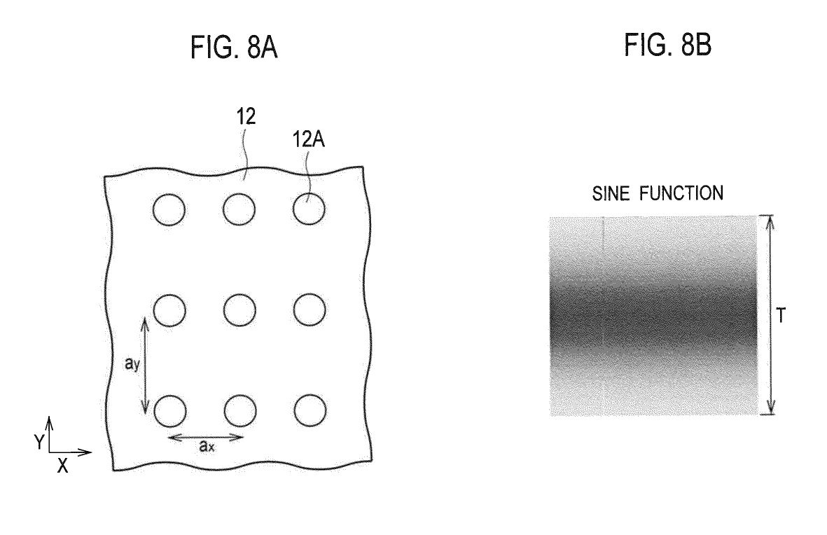

In the 2D-PC SEL according to the first embodiment, FIG. 8A shows the real space example of the lattice point for forming resonant-state (rectangular lattice) 12A in the 2D-PC layer 12, and FIG. 8B shows a conceptual diagram for explaining an aspect that the perturbation of the sine wave function is applied in the y-axial direction to the lattice point for forming resonant-state (rectangular lattice) 12A in the 2D-PC layer 12.

In the 2D-PC SEL according to the comparative example 2, there is no limitation to the period of sine function (perturbation) with respect to the period (a_{z}, a_{y}) of primitive lattice. On the other hand, in the 2D-PC SEL according to the first embodiment, the period T of sine function (perturbation) must be matched with the period (a_{z}, a_{y}) of primitive lattice. In the example of FIG. 8, it is limited to 2a_{y}=T.

Moreover, the wave number space corresponding to the Fourier transform of the real space in FIG. 8A is similarly illustrated as FIG. 7A, and the wave number space corresponding to the Fourier transform of the real space in FIG. 8B is similarly illustrated as FIG. 7B. The wave number vector k_{f}↑ and the diffraction vector k_{d}↑ are as shown in FIGS. 7A and 7B.

In the 2D-PC SEL according to the comparative example 2, there is no limitation to the diffraction vector k_{d}↑ for the surface light emission with respect to the wave number vector k_{f}↑ (=π/a_{y}). On the other hand, in the 2D-PC SEL according to the first embodiment, the wave number vector k_{f}↑ must be matched with the diffraction vector k_{d}↑. That is, an equation k_{f}↑=k_{d}↑ is realized.

The dielectric constant of the perturbation term in which the perturbation of the sine wave function is applied to the lattice point for forming resonant-state 12A to the dielectric constant ∈_{0.a}(r↑) of the lattice point for forming resonant-state 12A in the 2D-PC layer 12 can be expressed the equation, ∈₁(r↑) sin(k_{d}↑·r↑).

Accordingly, the dielectric constant ∈′(r↑) of the perturbation lattice point 12P in which the perturbation of the sine wave function is applied to the fundamental structure of the lattice point for forming resonant-state 12A in the 2D-PC layer 12 is expressed by the following equation.

∈′(r↑)=∈_{0,a}(r↑)+∈_{1,a}(r↑)sin(k_{d}↑·r↑) (3)

Although the lattice point for forming resonant-state 12A and the lattice points for light extraction 12C are used as different lattices in the comparative example 1, the surface emission-type laser can be achieved with the simplified structure by introducing the periodic perturbation into the lattice point for forming resonant-state 12A in the 2D-PC layer 12, in the 2D-PC SEL according to the first embodiment.

In the 2D-PC SEL according to the first embodiment, since only one type or two types of hole shape cannot exist periodically, and does not superimposed on each other, the fabrication thereof is easy.

According to the 2D-PC SEL according to the first embodiment, since there is provided the structure in which the periodic perturbation is applied to the refractive index, the size, or the depth of the lattice point for forming resonant-state 12A which forms periodic structure as the crystal lattice in the 2D-PC layer 12, the stable resonant-state can be formed, while being able to fabricate extremely easily the 2D-PC SEL.

### (Hole-Shape (Hole-Diameter) Modulation)

The hole diameter of the perturbation term in which the perturbation of the sine wave function is applied to the lattice point for forming resonant-state 12A to the hole diameter dₒ, (r↑) of the lattice point for forming resonant-state 12A in the 2D-PC layer 12 can be expressed the equation, d_{1,a}(r↑) sin (k_{d}↑−r↑)

dₐ(r↑)=d_{0,a}(r↑)+d_{1,a}(r↑)sin(k_{d}↑*r↑) (4)

In the 2D-PC SEL according to the first embodiment, the hole diameter dₐ(r↑) of the perturbation lattice point for forming-state 12P in which the periodic perturbation of the hole-shape (hole-diameter) modulation of the sine wave function is applied to the fundamental structure of the lattice point for forming resonant-state 12A in the 2D-PC layer 12 is expressed by the following equation:

dₐ′(r↑)=d_{0,a}(r↑)+d_{1,a}(r↑)sin {(π/a₁↑,π/a₂↑)·r↑} (5)

r↑=r₀↑+aₘₙ↑ (6)

aₘₙ↑=(ma₁↑,na₂↑) (7)

where m and n denote the integer, a_{m n}↑ is a position vector defined by the integral multiple (ma₁↑, na₂↑) of the lattice constants (a₁, a₂), and r₀↑ is an initial position vector. Accordingly, in the 2D-PC SEL according to the first embodiment, the arrangement of the perturbation lattice point 12P to which the periodic perturbation applied certainly corresponds to the position of the lattice point for forming resonant-state 12A.

According to the 2D-PC SEL according to the first embodiment, it can be considered it is the particular case where the diffraction vector k_{d}↑ is expressed with (π/a₁↑, π/a₂↑), as mentioned above.

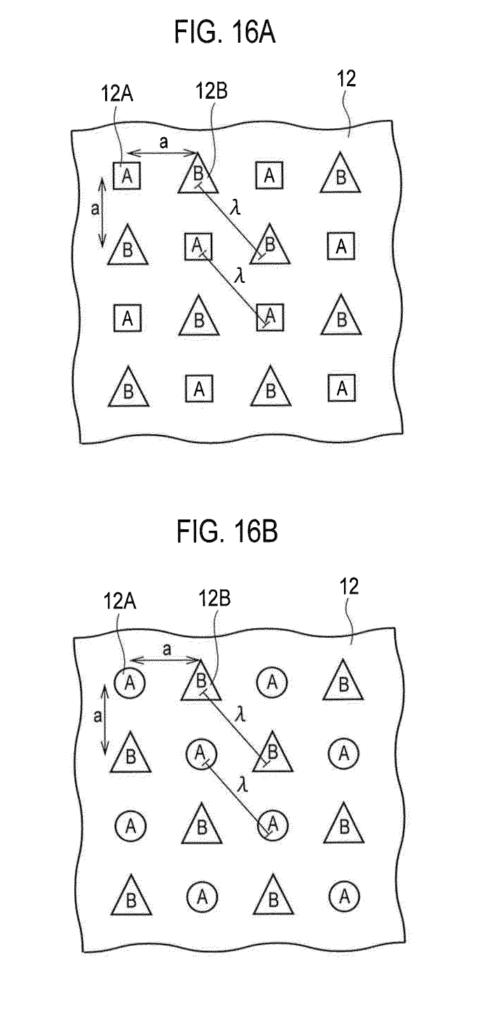

However, various shapes which cannot be expressed with the above-mentioned equations are also included in the 2D-PC SEL according to the first embodiment. As an example in which the various shapes cannot be expressed with simple expression, structure where a triangle lattice point and a square lattice point are arranged one after the other is also included therein (Refer to FIGS. 16A and 16B.).

### (Rectangular Lattice: M-Point)

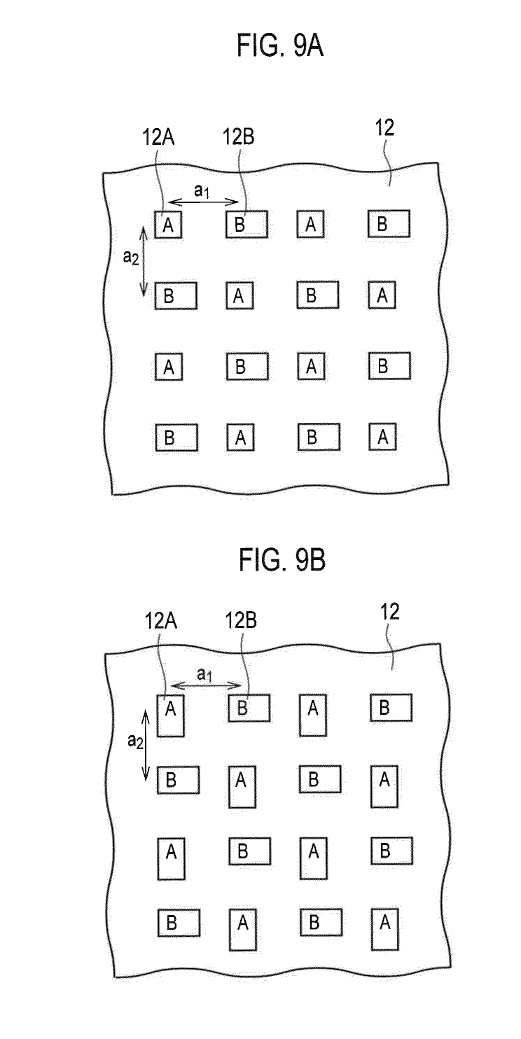

As examples of the rectangle lattice arrangement of lattice points for forming resonant-state 12A, 12B in the 2D-PC layer 12, FIG. 9A shows an example that the adjacent lattice points 12A and 12B have different shapes from each other, and FIG. 9B shows an example that the adjacent lattice points have the same shape, but the arrangement directions of the adjacent lattice points are different from each other, in the 2D-PC SEL according to the first embodiment. In this case, the lattice constant of the rectangular lattice is expressed with (a_{z}, a_{y})=(a₁, a₂). The hole shape of the lattice point for forming resonant-state 12A is a square, and the hole shape of the lattice point for forming resonant-state 12B is a rectangle, as shown in FIG. 9A. Alternatively, the hole shapes of the lattice points for forming resonant-state 12A, 12B are the same rectangle, but the arrangement directions of the lattice points 12A, 12B are different from each other, as shown in FIG. 9B.

The lattice points for forming resonant-state 12A and 12B diffract light waves at an M-point band edge in the photonic band structure of 2D-PC layer 12, as shown in FIGS. 9A and 9B. The lattice point for forming resonant-state 12B is arranged in the face-centered rectangle lattice having the lattice constants (2a₁, 2a₂) twice the lattice constants (a₁, a₂) of the rectangular lattice. Similarly, the lattice point for forming resonant-state 12A is arranged in the face-centered rectangle lattice having the lattice constants (2a₁, 2a₂) twice the lattice constants (a₁, a₂) of the rectangular lattice.

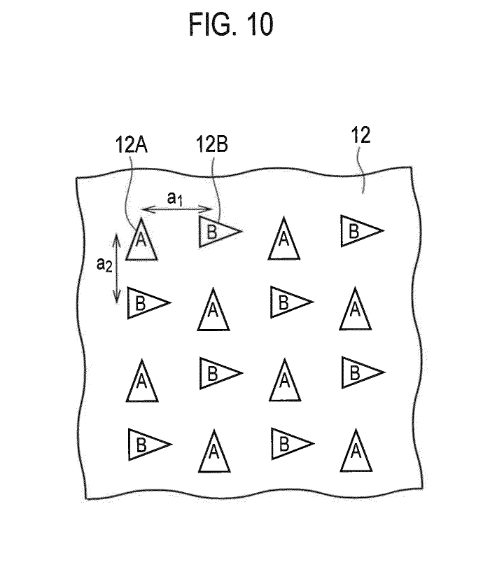

As examples of the rectangle lattice arrangement of lattice points for forming resonant-state 12A, 12B in the 2D-PC layer 12, FIG. 10 shows another example that the adjacent lattice points have the same shape, but the arrangement directions of the adjacent lattice points are different from each other, in the 2D-PC SEL according to the first embodiment. In this case, the lattice constant of the rectangular lattice is expressed with (aₓ, a_{y})=(a₁, a₂).

Alternatively, the hole shapes of the lattice points for forming resonant-state 12A, 12B are the same triangle, but the arrangement directions thereof are different from each other, as shown in FIG. 10.

The lattice points for forming resonant-state 12A and 12B diffract light waves at an M-point band edge in the photonic band structure of 2D-PC layer 12, as shown in FIG. 10. The lattice point for forming resonant-state 12B is arranged in the face-centered rectangle lattice having the lattice constants (2a₁, 2a₂) twice the lattice constants (a₁, a₂) of the rectangular lattice. Similarly, the lattice point for forming resonant-state 12A is arranged in the face-centered rectangle lattice having the lattice constants (2a₁, 2a₂) twice the lattice constants (a₁, a₂) of the rectangular lattice.

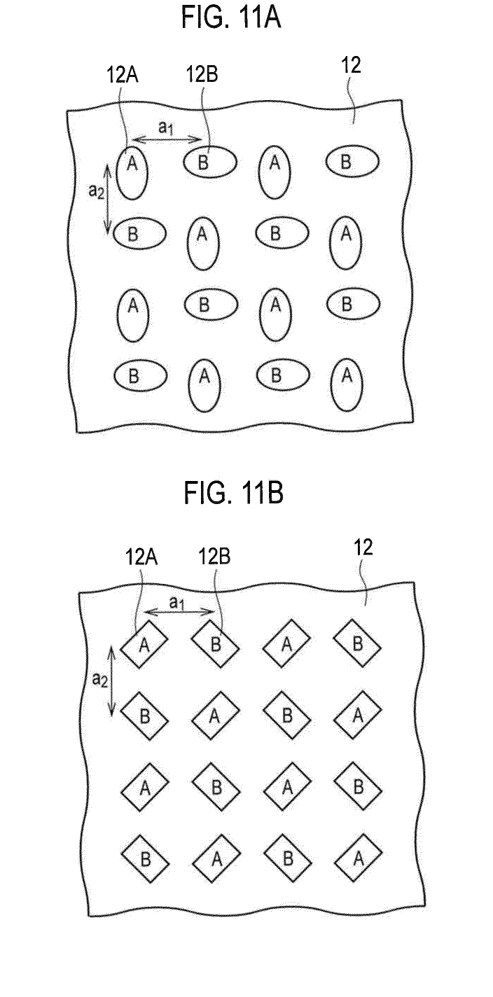

As examples of the rectangle lattice arrangement of lattice points for forming resonant-state 12A, 12B in the 2D-PC layer 12, FIGS. 11A and 11B show still another example that the adjacent lattice points 12A, 12B have the same shape, but the arrangement directions of the adjacent lattice points are different from each other, in the 2D-PC SEL according to the first embodiment. In this case, the lattice constant of the rectangular lattice is expressed with (aₓ, a_{y})=(a₁, a₂).

The hole shapes of the lattice points for forming resonant-state 12A, 12B are the same oval shape, but the arrangement directions thereof are different from each other, as shown in FIG. 11A. Alternatively, the hole shapes of the lattice points for forming resonant-state 12A, 12B are the same rectangle, but the arrangement directions thereof are different from each other, as shown in FIG. 11B.

The lattice points for forming resonant-state 12A and 12B diffract light waves at an M-point band edge in the photonic band structure of 2D-PC layer 12, as shown in FIGS. 11A and 11B. The lattice point for forming resonant-state 12B is arranged in the face-centered rectangle lattice having the lattice constants (2a₁, 2a₂) twice the lattice constants (a₁, a₂) of the rectangular lattice. Similarly, the lattice point for forming resonant-state 12A is arranged in the face-centered rectangle lattice having the lattice constants (2a₁, 2a₂) twice the lattice constants (a₁, a₂) of the rectangular lattice.

### Comparative Example 3

### Square Lattice: M-Point

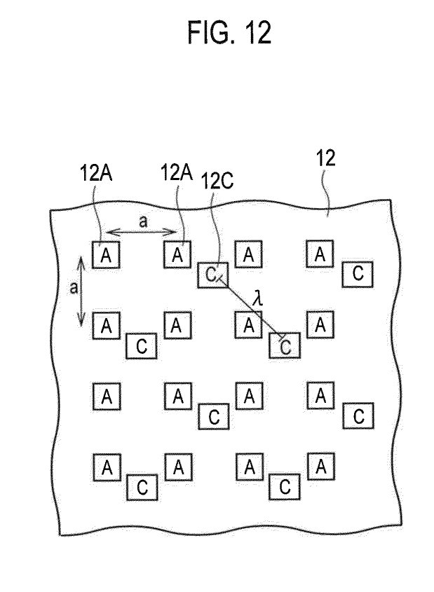

As shown in FIG. 12, a schematic plane configuration of the lattice point for forming resonant-state 12A and the lattice points for coupler 12C in the 2D-PC layer 12 applied to the M-point oscillation are arranged in a square-lattice shape, in a 2D-PC SEL according to a comparative example 3.

As shown in FIG. 12, each of the lattice point for forming resonant-state 12A and the lattice point for coupler 12C has a rectangular hole shape.

The lattice point for forming resonant-state 12A diffracts light waves at the M-point band edge in the photonic band structure of 2D-PC layer 12, as shown in FIG. 12. The lattice point for forming resonant-state 12A is arranged in the square lattice has the lattice constant a, as shown in FIG. 12. The lattice point for coupler 12C is arranged in the face-centered square lattice having twofold lattice constant 2a, and the pitch of the lattice point for coupler 12C in a diagonal line direction is equal to the wavelength in the medium λ of the PC layer 12. The lattice point for forming resonant-state 12A composes the resonator, and acts as the laser oscillation. The lattice point for coupler 12C composes the coupler, and acts as the light extraction.

In the comparative example 3, since the lattice point for forming resonant-state 12A and the lattice point for coupler 12C are used as different lattices, the lattice point for coupler 12C significantly affects the resonant-state form.

### (Square Lattice: M-Point)

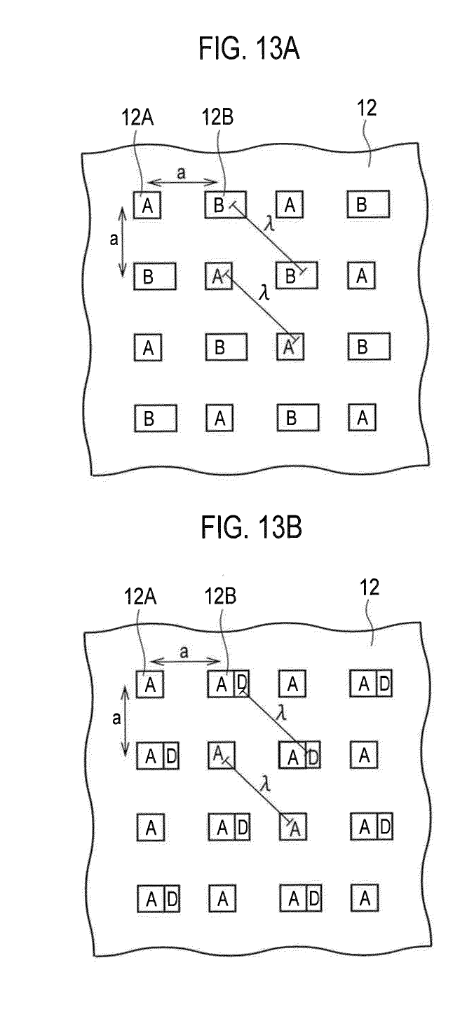

As examples of the square lattice arrangement of lattice points for forming resonant-state 12A, 12B in the 2D-PC layer 12, FIG. 13A shows an example that the adjacent lattice points 12A and 12B have different shapes from each other, in the 2D-PC SEL according to the first embodiment. Moreover, FIG. 13B shows an explanatory diagram for FIG. 13A. As shown in FIG. 13B, a portion D which is a difference between the adjacent lattice points 12A, 12B acts as the coupler. The lattice constant of the square lattice is expressed with a, in this case.

The hole shape of the lattice point for forming resonant-state 12A is a square, and the hole shape of the lattice point for forming resonant-state 12B is a rectangle, as shown in FIG. 13A.

The lattice points for forming resonant-state 12A, 12B diffract light waves at an M-point band edge in the photonic band structure of 2D-PC layer 12, as shown in FIG. 13B. The lattice point for forming resonant-state 12B is arranged in the face-centered square lattice having the lattice constant 2a twice the lattice constant a of the square lattice, and the pitch thereof in the diagonal line direction is equal to the wavelength in the medium λ of the PC layer 12. Similarly, the lattice point for forming resonant-state 12A is arranged in the face-centered square lattice having a lattice constant 2a twice the lattice constant a of the square lattice, and the pitch thereof in the diagonal line direction of the lattice point for forming resonant-state 12A is equal to the wavelength in the medium λ of the PC layer 12.

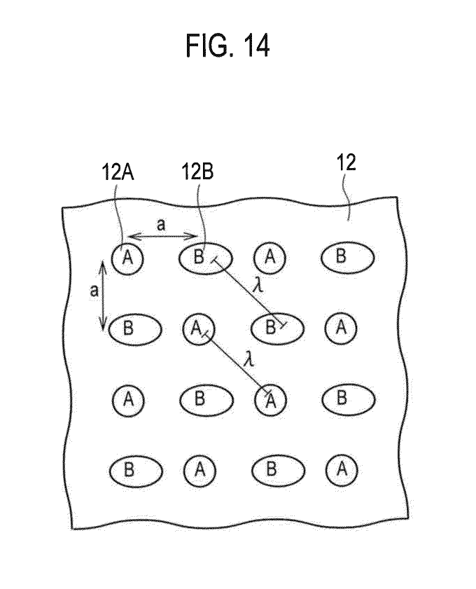

As examples of the square lattice arrangement of lattice points for forming resonant-state 12A, 12B in the 2D-PC layer 12, FIG. 14 shows another example that the adjacent lattice points 12A and 12B have different shapes from each other, in the 2D-PC SEL according to the first embodiment. The lattice constant of the square lattice is expressed with a, in this case.

The hole shape of the lattice point for forming resonant-state 12A is a circular shape, and the hole shape of the lattice point for forming resonant-state 12B is an oval shape, as shown in FIG. 14.

The lattice points for forming resonant-state 12A and 12B diffract light waves at an M-point band edge in the photonic band structure of 2D-PC layer 12, as shown in FIG. 14. The lattice point for forming resonant-state 12B is arranged in the face-centered square lattice having the lattice constant 2a twice the lattice constant a of the square lattice, and the pitch thereof in the diagonal line direction of the lattice point for forming resonant-state 12B is equal to the wavelength in the medium λ of the PC layer 12. Similarly, the lattice point for forming resonant-state 12A is arranged in the face-centered square lattice which has a lattice constant 2a twice the lattice constant a of the square lattice, and the pitch thereof in the diagonal line direction of the lattice point for forming resonant-state 12A is equal to the wavelength in the medium λ of the PC layer 12.

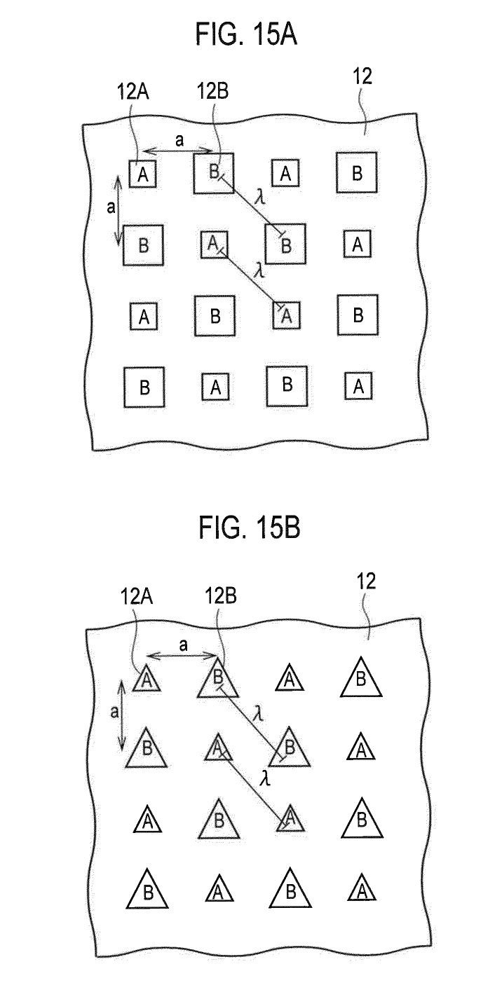

As examples of the square lattice arrangement of lattice points for forming resonant-state 12A, 12B in the 2D-PC layer 12, FIG. 15A shows an example that the adjacent lattice points 12A and 12B have rectangular shapes of which the sizes are different from each other, and FIG. 15B shows an example that the adjacent lattice points have triangular shapes of which the sizes are different from each other, in the 2D-PC SEL according to the first embodiment. The lattice constant of the square lattice is expressed with a, in this case.

The hole shape of the lattice point for forming resonant-state 12A is a relatively small four-square, and the hole shape of the lattice point for forming resonant-state 12B is a relatively large four-square, as shown in FIG. 15A. Alternatively, the hole shape of the lattice point for forming resonant-state 12A is a relatively small equilateral triangle, and the hole shape of the lattice point for forming resonant-state 12B is a relatively large equilateral triangle, as shown in FIG. 15B.

The lattice points for forming resonant-state 12A and 12B diffract light waves at an M-point band edge in the photonic band structure, as shown in FIGS. 15A and 15B. The lattice point for forming resonant-state 12B is arranged in the face-centered square lattice having the lattice constant 2a twice the lattice constant a of the square lattice, and the pitch thereof in the diagonal line direction of the lattice point for forming resonant-state 12B is equal to the wavelength in the medium λ of the PC layer 12. Similarly, the lattice point for forming resonant-state 12A is arranged in the face-centered square lattice which has a lattice constant 2a twice the lattice constant a of the square lattice, and the pitch thereof in the diagonal line direction of the lattice point for forming resonant-state 12A is equal to the wavelength in the medium λ of the PC layer 12.

As examples of the square lattice arrangement of lattice points for forming resonant-state 12A, 12B in the 2D-PC layer 12, FIGS. 16A and 16B show still another example that the adjacent lattice points 12A and 12B have different shapes from each other, in the 2D-PC SEL according to the first embodiment. In the case, the lattice constant of the square lattice is expressed with a.

The hole shape of the lattice point for forming resonant-state 12A is a square, and the hole shape of the lattice point for forming resonant-state 12B is a triangle, as shown in FIG. 16A. Alternatively, the hole shape of the lattice point for forming resonant-state 12A is a circular shape, and the hole shape of the lattice point for forming resonant-state 12B is a triangle, as shown in FIG. 16B.

The lattice points for forming resonant-state 12A and 12B diffract light waves at an M-point band edge in the photonic band structure, as shown in FIGS. 16A and 16B. The lattice point for forming resonant-state 12B is arranged in the face-centered square lattice having the lattice constant 2a twice the lattice constant a of the square lattice, and the pitch thereof in the diagonal line direction of the lattice point for forming resonant-state 12B is equal to the wavelength in the medium λ of the PC layer 12. Similarly, the lattice point for forming resonant-state 12A is arranged in the face-centered square lattice which has a lattice constant 2a twice the lattice constant a of the square lattice, and the pitch thereof in the diagonal line direction of the lattice point for forming resonant-state 12A is equal to the wavelength in the medium λ of the PC layer 12.

### (FFP)

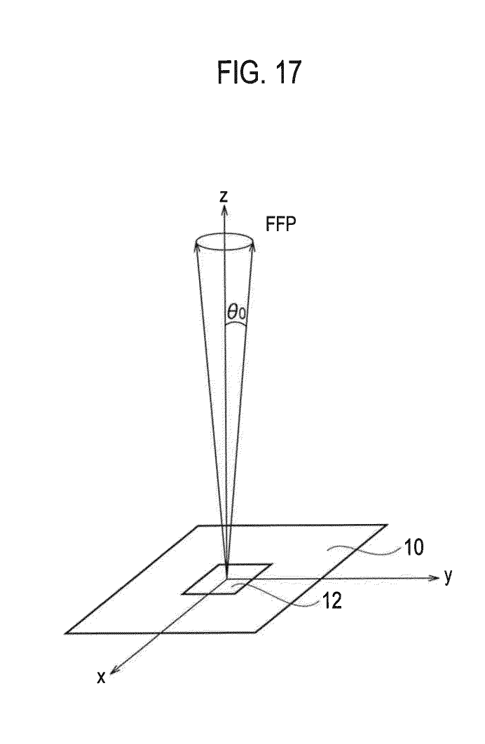

FIG. 17 shows schematically FFP of the lattice point for forming resonant-state (square lattice M-point) in the 2D-PC layer 12, for example, in the 2D-PC SEL according to the first embodiment. More specifically, in the three-dimensional space (x, y, z), the FFP of the beam spread angle θ₀ is obtained from the z-axial direction normal to the surface of the 2D-PC layer 12 arranged on the substrate 10.

According to the first embodiment, there can be provided the 2D-PC SEL which can vertically emit laser beams with simplified structure, in the non-radiative resonator structure, e.g. the M-point resonator.

### Second Embodiment

A schematic bird's-eye view structure of a 2D-PC SEL according to a second embodiment is similarly illustrated as FIG. 1.

The 2D-PC SEL according to the second embodiment includes: a PC layer 12; a lattice point for forming resonant-state 12A periodically arranged in the PC layer 12, and configured so that PC layer 12 a light wave at a band edge in photonic band structure is diffracted in the plane of the PC layer 12; and a perturbation lattice point periodically arranged in the PC layer 12, and configured so that the light wave at the band edge of the photonic band structure in the PC layer 12 is diffracted in the plane of the PC layer 12, and diffracted in a direction normal to the surface of the PC layer 12.

In this case, “periodic perturbation” for diffracting the light wave in the direction normal to the surface of the PC layer 12 is applied to a part of the lattice point for forming resonant-state 12A, and thereby the perturbation lattice point 12P is formed. The term “periodic perturbation” used therein means that modulation is periodically applied to the PC layer 12 for forming periodic structure in the lattice point for forming resonant-state 12A.

The lattice point for forming resonant-state 12A to which a perturbation was applied is expressed with a lattice point perturbation 12P. The periodic modulation may be refractive index modulation, may be hole-size modulation, or may be hole-depth modulation. Furthermore, the periodic modulation may be a hole-depth modulation or a hole-depth modulation.

Also in the 2D-PC SEL according to the second embodiment, the above-mentioned perturbation lattice point 12P can be formed in the same manner as the lattice point for forming resonant-state 12B in the first embodiment.

More specifically, the adjacent lattice point for forming resonant-state 12A and perturbation lattice point 12P may have different shapes from each other.

Moreover, the adjacent lattice point for forming resonant-state 12A and perturbation lattice point 12P may have different sizes from each other.

Moreover, the hole depth of the lattice point for forming resonant-state 12A and the hole depth of the perturbation lattice point 12P may be different from each other.

Moreover, the refractive index of the lattice point for forming resonant-state 12A and the refractive index of the perturbation lattice point 12P may be different from each other.

Moreover, the shape of the lattice point for forming resonant-state 12A and the perturbation lattice point 12P are the same, but the arrangement directions thereof may be different from each other.

Moreover, the lattice point for forming resonant-state 12A and the perturbation lattice point 12P are arranged in any one selected from the group consisting of a square lattice, a rectangular lattice, and a triangular lattice.

Moreover, the lattice point for forming resonant-state 12A and the perturbation lattice point 12P may be arranged in a square lattice or a rectangular lattice. In this case, light waves at the Γ point (gamma point), the X point, or the M point in the photonic band structure of the PC layer 12 can be diffracted in the direction normal to the surface of the PC layer 12.

Moreover, the lattice point for forming resonant-state 12A and the perturbation lattice point 12P may be arranged in the face-centered rectangle lattice or the triangular lattice. In this case, light waves at the Γ point (gamma point), the X point, or the J point in the photonic band structure of the PC layer 12 can be diffracted in the direction normal to the surface of the PC layer 12.

Moreover, the lattice points for forming resonant-state 12A and the perturbation lattice point 12P may be provided with any one of a polygonal shape, a circular shape, an ellipse shape, or an oval shape. The polygonal shape includes a triangle, a square, a four-square, a rectangle, etc.

In the same manner as FIG. 1, the 2D-PC SEL according to the second embodiment includes: a substrate 24; a first cladding layer 10 disposed on the substrate 24; a second cladding layer 16 disposed on the first cladding layer 10; and an active layer 14 inserted between the first cladding layer 10 and the second cladding layer 16. In this case, the first cladding layer 10 may be formed of a p type semiconductor layer, and the second cladding layer 16 may be formed of an n type semiconductor layer. Alternatively, the electrical conductivity of the semiconductor layer may be reverse to each other.

Furthermore, in the same manner as FIG. 1, the 2D-PC SEL according to the second embodiment includes: a contact layer 18 arranged on the second cladding layer 16; a window layer 20 disposed on a surface light emission region on the contact layer 18, and configured to extract a laser beam; a window-like upper electrode 22 disposed on the window layer 20; and a lower electrode 26 disposed on a back side surface of the substrate 24.

In the same manner as FIG. 1, the PC layer 12 may be inserted between the first cladding layer 10 and the second cladding layer 16 so as to be adjacent to the active layer 14 in a direction normal to the surface of the active layer 14. In this case, the active layer 14 may be formed of an MQW layer, for example.

Moreover, the PC layer 12 may be inserted between the first cladding layer 10 and the active layer 14, in the same manner as FIG. 1.

Moreover, as shown in FIG. 1, a carrier blocking layer 13 is inserted between the active layer 14 and the PC layer 12 so that carriers may be effectively acquired in the active layer 14 composed of the MQW layer, and a carrier injection from the active layer 14 to the PC layer 12 may be blocked.

Moreover, the PC layer 12 may be inserted between the second cladding layer 16 and the active layer 14.

### (Γ-Point (Gamma-Point) Oscillation: Square Lattice)

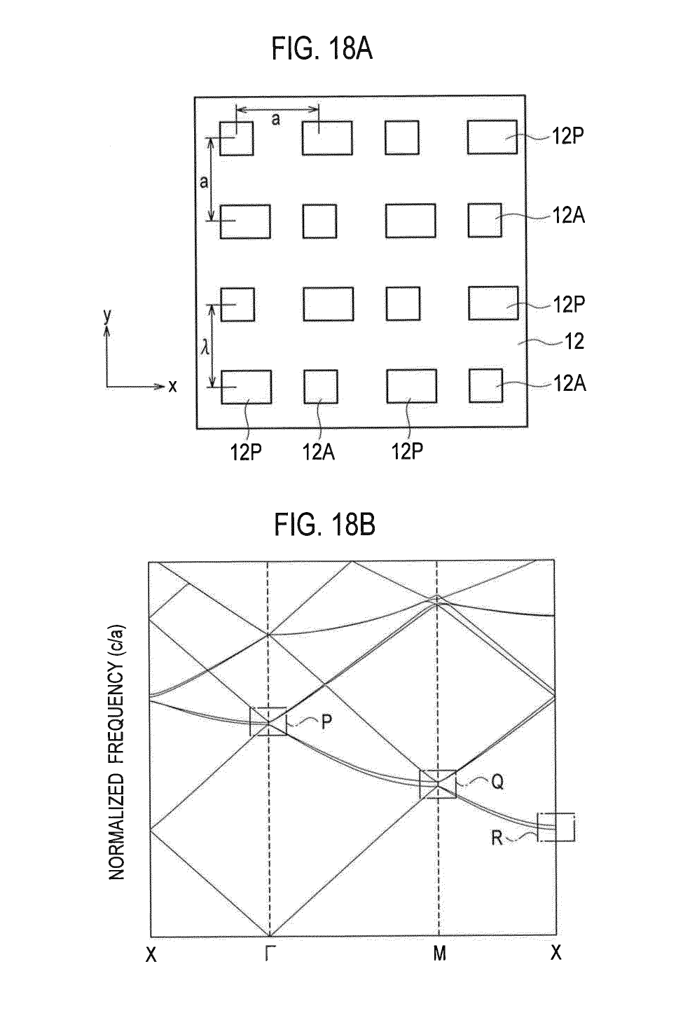

In the 2D-PC SEL according to the second embodiment, FIG. 18A shows a schematic plane configuration (example of square lattice arrangement) of the lattice point for forming resonant-state 12A in the 2D-PC layer 12 and the perturbation lattice point 12P applied to the Γ-point (gamma-point) oscillation, and FIG. 18B shows a relationship between the normalized frequency [unit: c/a] and the wave number vector in the 2D-PC band structure.

In the photonic band structure, a portion of which the inclination is 0 is called a band edge. At the band edge, the PC functions as an optical resonator, since a group velocity of light becomes 0 and then a standing wave is formed. Moreover, the perturbation lattice point 12P is formed by applying the periodic perturbation to a part of the lattice point for forming resonant-state 12A.

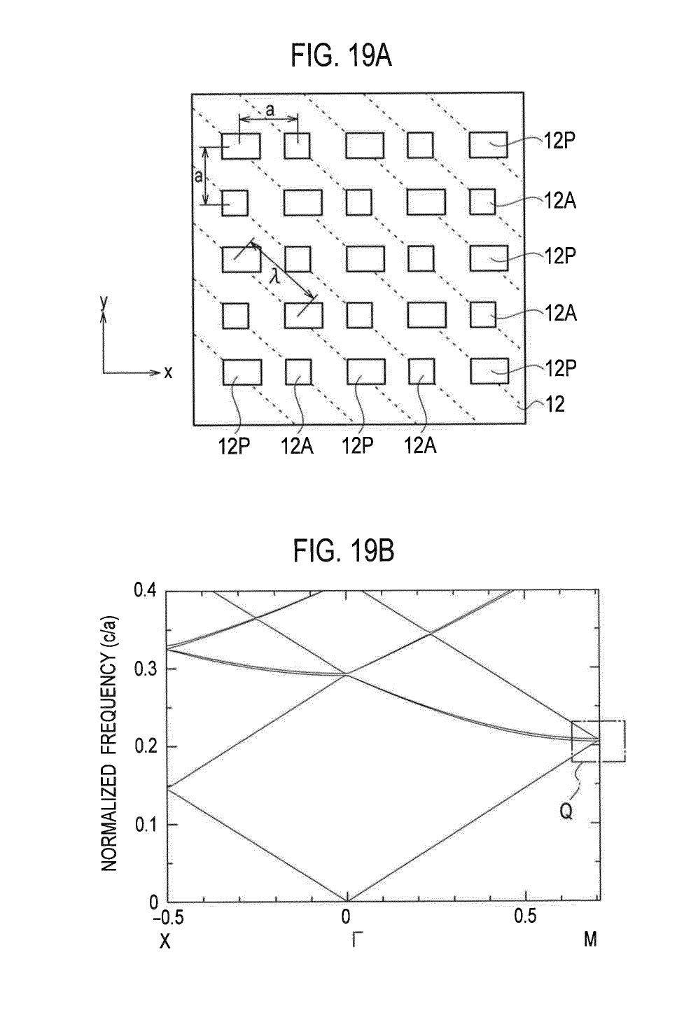

In the 2D-PC SEL according to the second embodiment, the lattice point for forming resonant-state 12A for diffracting the light wave at the Γ-point (gamma-point) band edge (near the region R shown in FIG. 18B) in the photonic band structure in the PC layer 12 is arranged in the square lattice shape having the lattice constant a, as shown in FIG. 19A. Moreover, as a result of applying the periodic perturbation to apart of the lattice point for forming resonant-state 12A to form the perturbation lattice point 12P, the perturbation lattice point 12P is arranged in the face-centered square lattice having the lattice constant 2a twice the lattice constant of the square lattice. Thus, there can be provided the 2D-PC SEL which can vertically emit laser beams with simplified structure, also in the radiation resonator structure, e.g. the Γ-point (gamma-point) resonator etc.

### (M-Point Oscillation: Square Lattice)

FIG. 19A shows a schematic plane configuration of the lattice point for forming resonant-state 12A and the perturbation lattice point 12P in the 2D-PC layer 12 applied to the M-point oscillation, in the 2D-PC SEL according to the second embodiment. Moreover, FIG. 19B shows a relationship between the normalized frequency and the wave number vector, in the 2D-PC band structure corresponding to FIG. 19A. The periodic perturbation for diffracting the light waves in the direction normal to the surface of the PC layer 12 is applied to a part of the lattice point for forming resonant-state 12A, and thereby the perturbation lattice point 12P is formed.

In the 2D-PC SEL according to the second embodiment, the lattice point for forming resonant-state 12A for diffracting the light waves at the M-point band edge (near the region Q shown in FIG. 19B) in the photonic band structure in the PC layer 12 is arranged in the square lattice shape having the lattice constant a, as shown in FIG. 19A. Moreover, as a result of forming the lattice point for forming resonant-state 12A by applying the periodic perturbation to a part of the lattice point for forming resonant-state 12A, the perturbation lattice point 12P is arranged in the face-centered square lattice having twofold lattice constant 2a, and the pitch of the perturbation lattice point 12P in a diagonal line direction is equal to the wavelength in the medium λ of the PC layer 12.

In the 2D-PC SEL according to the second embodiment, if the oscillation at the M-point band edge of photonic band structure is used, although the periodic structure of PC has only a function of the resonant-state form for the oscillation, light can be extracted by arranging the perturbation lattice point 12P in which the periodic perturbation is applied to the lattice point for forming resonant-state 12A.

In addition, the 2D-PC SEL according to the second embodiment can operate in a single mode stable in a large area. More specifically, in the 2D-PC SEL according to the second embodiment, the single mode is maintainable also in a large area since electromagnetic field distribution is defined by the lattice point for forming resonant-state 12A and the perturbation lattice point 12P formed in the PC layer 12. Accordingly, ii is easy to perform processing for collecting a watt-class output laser light into one small point through a lens.

For example, in FIG. 1, the sizes of the PC layer 12 are approximately 700 μm×approximately 700 μm.

Moreover, in an example of NFP, oscillations are also achieved from large area oscillations of approximately 100-μm square to super-large area oscillations of an approximately several 100-μm square. Room-temperature continuous oscillations with the wavelength of approximately 950 nm are obtained with Full Width at Half Maximum (FWHM) being approximately 950 nm in an oscillation spectrum.

The lattice point for forming resonant-state 12A can be arranged in a pitch of the period of light, for example. For example, supposing that the hole is fulfilled with an air, the pitch of the air/semiconductor is can be arranged in a period of approximately 400 nm in the optical communication band, and can be arranged in a period of approximately 230 nm in the blue light.

Moreover, the diameter and the depth of the lattice point for forming resonant-state 12A currently made as an experiment are respectively approximately 120 nm and approximately 115 nm, for example, and the pitch thereof is approximately 286 nm, for example. Such numerical examples can be appropriately modified in accordance with materials composing the substrate 10 and the active layer 14, materials of the 2D-PC layer 12, the wavelength in the medium, etc.

For example, in the 2D-PC SEL according to the second embodiment to which GaAs/AlGaAs based materials are applied, the wavelength λ in the medium of the 2D-PC layer 12 is from approximately 200 nm to approximately 300 nm, and output laser light wavelengths are from approximately 900 nm to approximately 915 nm.

In addition, if the perturbation lattice point 12P is subjected to the refractive index modulation, the perturbation lattice point 12P may be filled up with semiconductor layers differing in refractive index, for example. For example, the lattice point for forming perturbation-state 12P may be formed by filling up the GaAs layer with the AlₓGa₁₋ₓAs layer modulated with the composition ratio x. For example, during a fabricating process for welding the 2D-PC layer 12, if the perturbation lattice point 12P, it is effective to fill up with the semiconductor layers differing in the refractive index in order to avoid such a deformation.

### (X-Point Oscillation: Square Lattice)

In the oscillation at the X-point band edge in the photonic band structure, although the periodic structure of the PC has only a function of optical amplification for the oscillation, the light can be extracted by disposing periodic perturbation structure for diffracting the light in the same plane as the aforementioned periodic structure.

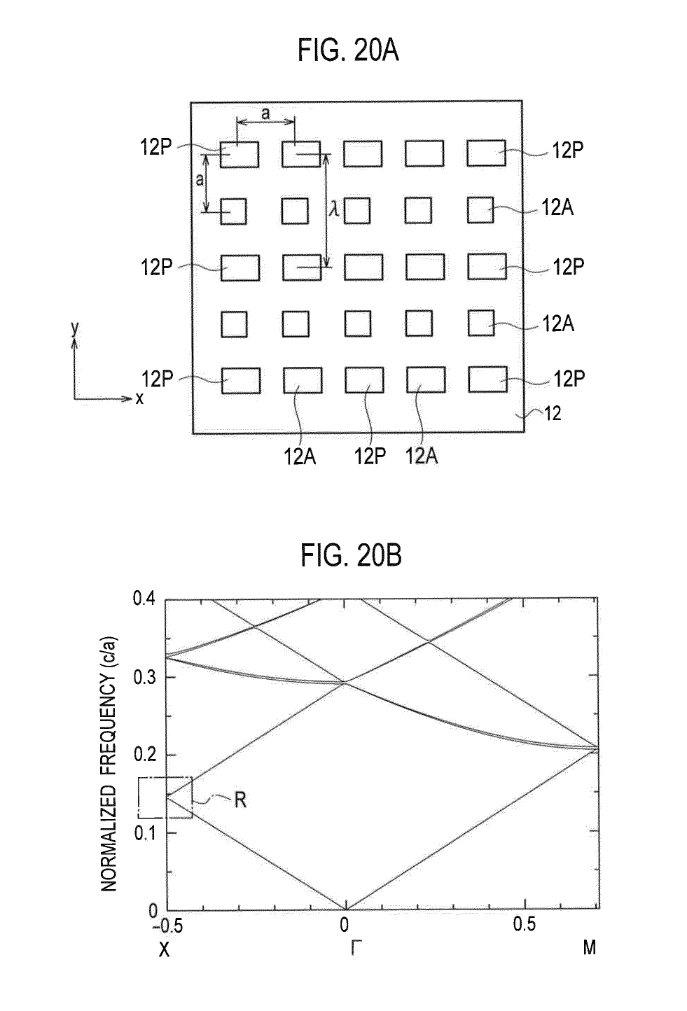

In the 2D-PC SEL according to the second embodiment, as shown in FIG. 20A, a schematic plane configuration of the lattice point for forming resonant-state 12A and the perturbation lattice point 12P in the 2D-PC layer 12 applied to the M-point oscillation are arranged in the square lattice. Moreover, FIG. 20B shows a relationship between the normalized frequency and the wave number vector, in the 2D-PC band structure corresponding to FIG. 20A. The periodic perturbation for diffracting the light waves in the direction normal to the surface of the PC layer 12 is applied to a part of the lattice point for forming resonant-state 12A, and thereby the perturbation lattice point 12P is formed.

In the 2D-PC SEL according to the second embodiment, the lattice point for forming resonant-state 12A for diffracting the light waves at the X-point band edge (near the region P shown in FIG. 20B) in the photonic band structure in the PC layer 12 is arranged in the square lattice shape having the lattice constant a, as shown in FIG. 20A. Moreover, as a result of applying the periodic perturbation to apart of the lattice point for forming resonant-state 12A to form the perturbation lattice point 12P, the perturbation lattice point 12P is arranged in the rectangular lattice having the lattice constants (a, 2a). In this case, the lattice constant 2a is equal to the wavelength in the medium λ of the PC layer 12.

### (X-Point Oscillation: Triangular Lattice)

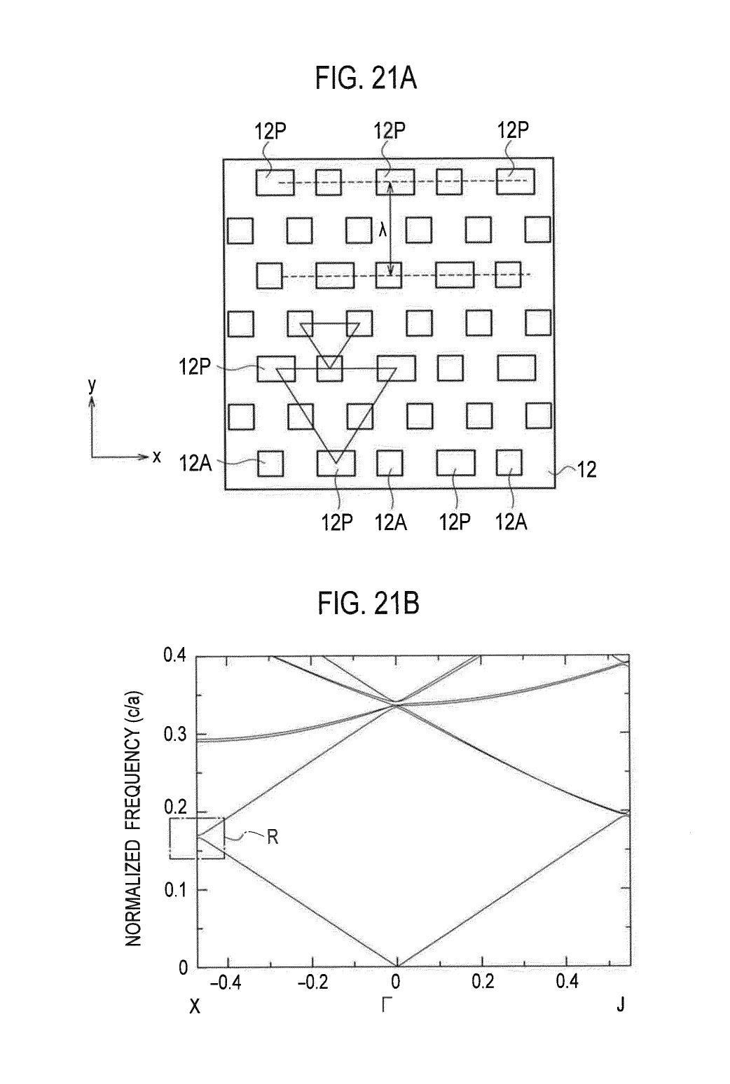

As shown in FIG. 21A, a schematic plane configuration of the lattice point for forming resonant-state 12A and the perturbation lattice point 12P in the 2D-PC layer 12 applied to the X-point oscillation is arranged in the triangular lattice shape, in the 2D-PC SEL according to the second embodiment. Moreover, FIG. 21B shows a relationship between the normalized frequency and the wave number vector, in the 2D-PC band structure corresponding to FIG. 21A. The periodic perturbation for diffracting the light waves in the direction normal to the surface of the PC layer 12 is applied to a part of the lattice point for forming resonant-state 12A, and thereby the perturbation lattice point 12P is formed.

In the 2D-PC SEL according to the second embodiment, the lattice point for forming resonant-state 12A for diffracting the light wave at the X-point band edge (near the region R shown in FIG. 21B) in the photonic band structure in the PC layer 12 is arranged in the first triangular lattice shape, as shown in FIG. 21A. Moreover, as a result of applying the periodic perturbation to a part of the lattice point for forming resonant-state 12A to form the perturbation lattice point 12P, the perturbation lattice point 12P is arranged in a second triangular lattice having the pitch twice the pitch of the first triangular lattice, and the height in the planar view of the second triangular lattice is equal to the wavelength in the medium λ of the PC layer 12.

### (J-Point Oscillation: Triangular Lattice)

In the 2D-PC SEL according to the second embodiment, although the periodic structure of the PC has only a function of optical amplification for the oscillation in the oscillation at the J-point band edge in the photonic band structure, the light can be extracted by disposing periodic perturbation structure for diffracting the light in the same plane as the aforementioned periodic structure.

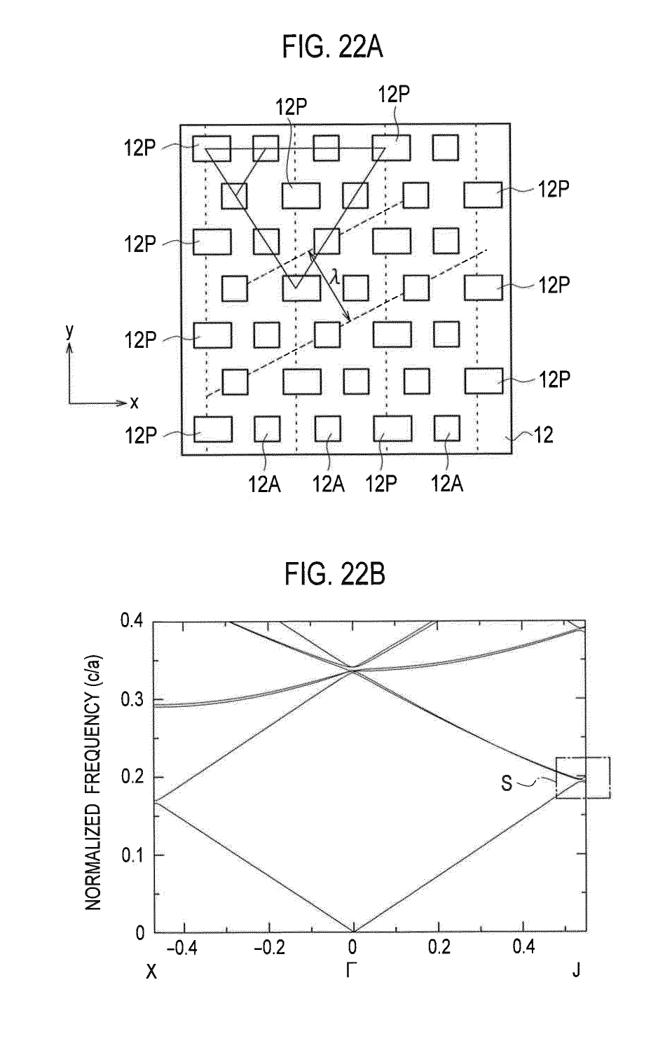

As shown in FIG. 22A, the lattice point for forming resonant-state 12A and the perturbation lattice point 12P in the 2D-PC layer 12 applied to the J-point oscillation are arranged in the triangular lattice shape, in the 2D-PC SEL according to the second embodiment. Moreover, FIG. 22B shows a relationship between the normalized frequency and the wave number vector, in the 2D-PC band structure corresponding to FIG. 22A. The periodic perturbation for diffracting the light waves in the direction normal to the surface of the PC layer 12 is applied to a part of the lattice point for forming resonant-state 12A, and thereby the perturbation lattice point 12P is formed.

In the 2D-PC SEL according to the second embodiment, the lattice point for forming resonant-state 12A for diffracting the light wave at the J-point band edge (near the region S shown in FIG. 22B) in the photonic band structure in the PC layer 12 is arranged in the first triangular lattice shape, as shown in FIG. 22A. Moreover, as a result of applying the periodic perturbation to a part of the lattice point for forming resonant-state 12A to form the perturbation lattice point 12P, the perturbation lattice point 12P is arranged in the face-centered triangular lattice having the pitch 3 times larger than the pitch of the first triangular lattice, and the length of one side of the face-centered triangular lattice is equal to twice the wavelength in the medium λ of the PC layer 12.

### (X-Point Oscillation: Rectangular Lattice)

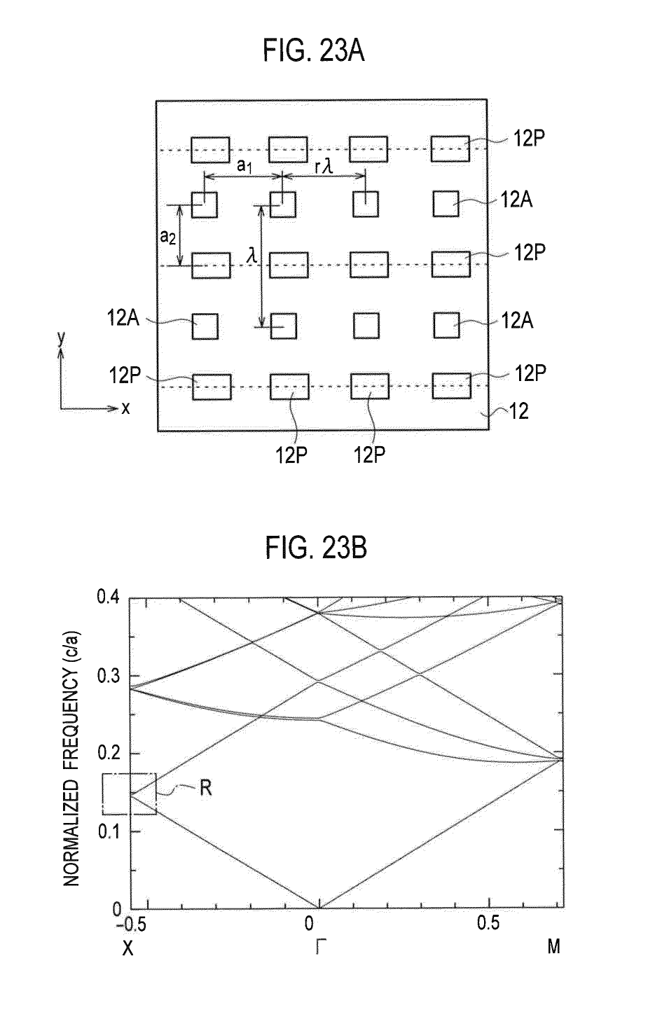

As shown in FIG. 23A, a schematic plane configuration of the lattice point for forming resonant-state 12A and the perturbation lattice point 12P in the 2D-PC layer 12 applied to the X-point oscillation is arranged in the rectangular lattice shape (example of a₁>a₂), in the 2D-PC SEL according to the second embodiment. Moreover, FIG. 23B shows a relationship between the normalized frequency and the wave number vector, in the 2D-PC band structure corresponding to FIG. 23A. The periodic perturbation for diffracting the light waves in the direction normal to the surface of the PC layer 12 is applied to a part of the lattice point for forming resonant-state 12A, and thereby the perturbation lattice point 12P is formed.

In the 2D-PC SEL according to the second embodiment, the lattice point for forming resonant-state 12A for diffracting the light wave at the X-point band edge (near the region R shown in FIG. 23B) in the photonic band structure in the PC layer 12 is arranged in a first rectangular lattice shape having the lattice constants (a₁, a₂), as shown in FIG. 23A. Moreover, as a result of applying the periodic perturbation to a part of the lattice point for forming resonant-state 12A to form the perturbation lattice point 12P, the perturbation lattice point 12P is arranged in the second rectangular lattice having the lattice constants (a₁, 2a₂). In this case, the lattice constants (a₁, 2a₂) of the second rectangular lattice is equal to r-times larger than the wavelength λ in the medium and to the wavelength λ in the medium, with respect to the aspect ratio r=a₁/a₂ (where r≠1) defined with the lattice constants (a₁, a₂).

### (X-point Oscillation: Rhombic Lattice)

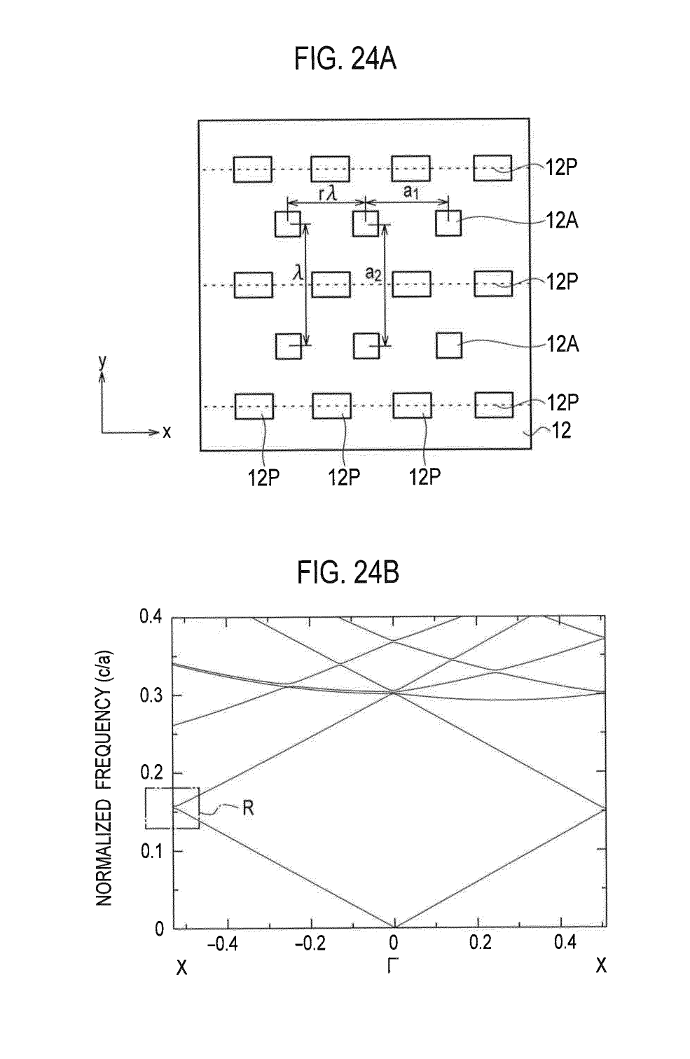

As shown in FIG. 24A, a schematic plane configuration of the lattice point for forming resonant-state 12A and the perturbation lattice point 12P in the 2D-PC layer 12 applied to the X-point oscillation is arranged in the rhombic lattice, in the 2D-PC SEL according to the second embodiment. Moreover, FIG. 24B shows a relationship between the normalized frequency and the wave number vector, in the 2D-PC band structure corresponding to FIG. 24A. The periodic perturbation for diffracting the light waves in the direction normal to the surface of the PC layer 12 is applied to a part of the lattice point for forming resonant-state 12A, and thereby the perturbation lattice point 12P is formed.

In the 2D-PC SEL according to the second embodiment, the lattice point for forming resonant-state 12A for diffracting the light wave at the X-point band edge (near the region R shown in FIG. 24B) in the photonic band structure in the PC layer 12 is arranged in the rhombic lattice having the lattice constants (a₁, a₂), as shown in FIG. 24A. Moreover, as a result of applying the periodic perturbation to a part of the lattice point for forming resonant-state 12A to form the perturbation lattice point 12P, the perturbation lattice point 12P is arranged in the rectangular lattice having the lattice constants (a₁, a₂). In this case, the lattice constants of the rectangular lattice is equal to r-times larger than the wavelength Ain the medium and to the wavelength λ in the medium, with respect to the aspect ratio r=a₁/a₂ (where r≠1) defined with the lattice constants (a₁, a₂).

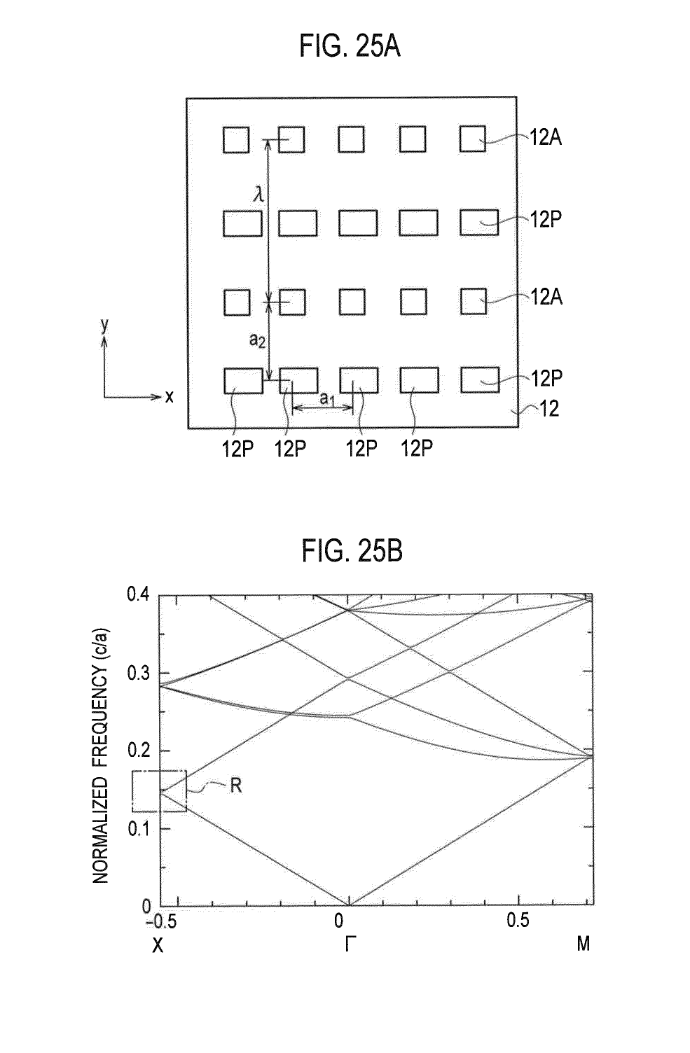

(X-Point Oscillation: Rectangular Lattice) In the 2D-PC SEL according to the second embodiment, as shown in FIG. 25A, a schematic plane configuration of the lattice point for forming resonant-state 12A and the perturbation lattice point 12P in the 2D-PC layer 12 applied to the X-point oscillation are arranged in the rectangular lattice shape (example of a₁<a₂) having the lattice constants (a₁, a₂). Moreover, FIG. 25B shows a relationship between the normalized frequency and the wave number, in the 2D-PC band structure corresponding to FIG. 25A. The periodic perturbation for diffracting the light waves in the direction normal to the surface of the PC layer 12 is applied to a part of the lattice point for forming resonant-state 12A, and thereby the perturbation lattice point 12P is formed.

In the 2D-PC SEL according to the second embodiment, the lattice point for forming resonant-state 12A for diffracting the light wave at the X-point band edge (near the region R shown in FIG. 25B) in the photonic band structure in the PC layer 12 is arranged in a first rectangular lattice shape having the lattice constants (a₁, a₂), as shown in FIG. 25A. Moreover, as a result of applying the periodic perturbation to a part of the lattice point for forming resonant-state 12A to form the perturbation lattice point 12P, the perturbation lattice point 12P is arranged in the rectangular lattice having the lattice constants (a₁, 2a₂). In this case, the lattice constants (a₁, 2a₂) of the second rectangular-lattice shape are respectively equal to a1 and the wavelength in the medium λ (=2a₂).

### (X-Point Oscillation: Rhombic Lattice)

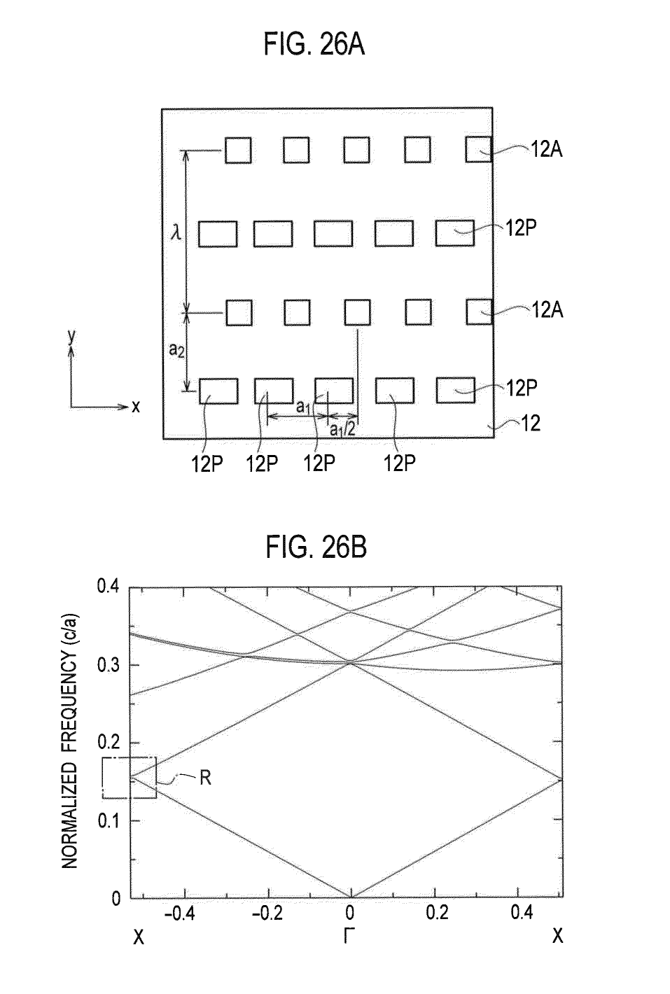

As shown in FIG. 26A, a schematic plane configuration of the lattice point for forming resonant-state 12A and the perturbation lattice point 12P in the 2D-PC layer 12 applied to the X-point oscillation is arranged in the rhombic lattice, in the 2D-PC SEL according to the second embodiment. Moreover, FIG. 26B shows a relationship between the normalized frequency and the wave number, in the 2D-PC band structure corresponding to FIG. 26A. The periodic perturbation for diffracting the light waves in the direction normal to the surface of the PC layer 12 is applied to a part of the lattice point for forming resonant-state 12A, and thereby the perturbation lattice point 12P is formed.

In the 2D-PC SEL according to the second embodiment, the lattice point for forming resonant-state 12A for diffracting the light wave at the X-point band edge (near the region R shown in FIG. 26B) in the photonic band structure in the PC layer 12 is arranged in the rhombic lattice having the lattice constants (a₁, 2a₂), as shown in FIG. 26A. Moreover, as a result of applying the periodic perturbation to a part of the lattice point for forming resonant-state 12A to form the perturbation lattice point 12P, the perturbation lattice point 12P is arranged in the rectangular lattice having the lattice constants (a₁, 2a₂). In this case, the lattice constant of the rectangular lattice is equal to a1 and the wavelength λ in the medium and (=2a₂) with respect to the lattice constants (a₁, a₂) of the rhombic lattice.

According to the second embodiment, there can be provided the 2D-PC SEL which can vertically emit laser beams with simplified structure, in the non-radiative resonator structure, e.g. the M-point resonator.

### (Control of Beam Spread Angle: Resonator Region RP and Perturbation Region PP)

The resonator region RP is a region where the lattice point for forming resonant-state 12A is arranged in the PC layer 12, and the perturbation region PP is a region where the perturbation 12P is arranged in the PC layer 12. The lattice point for forming resonant-state 12A and the perturbation lattice point 12P in which the periodic perturbation is applied to a part of the lattice point for forming resonant-state 12A are coexisted with each other to be arranged in the perturbation region PP.

In the resonator region RP and the perturbation region PP, the lattice point for forming resonant-state 12A and the perturbation lattice point 12P can be arranged in any one selected from the group consisting of a square lattice, a rectangular lattice, and a triangular lattice.

Moreover, in the resonator region RP and the perturbation region PP, the lattice point for forming resonant-state 12A and the perturbation lattice point 12P can be arranged in the square lattice or the rectangular lattice, and light waves at the Γ point (gamma point), the X point, or the M point in the photonic band structure of the PC layer 12 can be diffracted in the direction normal to the surface of the PC layer 12.

Moreover, in the resonator region RP and the perturbation region PP, the lattice point for forming resonant-state 12A and the perturbation lattice point 12P can be arranged in the face-centered rectangle lattice (rhombic lattice) or the triangular lattice, and Light waves at the Γ point (gamma point), the X point, or the J point in the photonic band structure of the PC layer 12 can be diffracted in the direction normal to the surface of the PC layer 12.

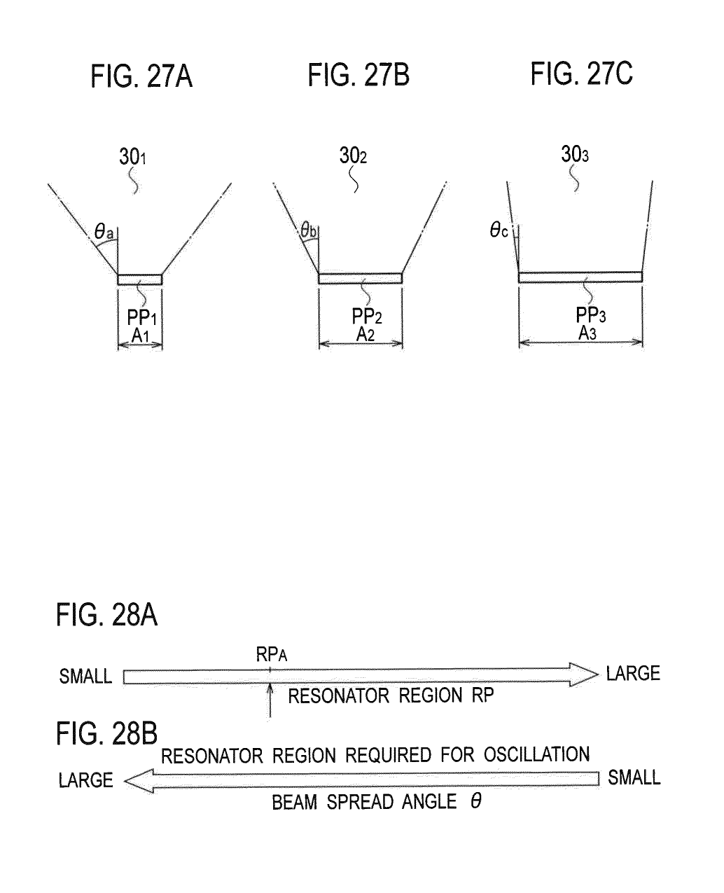

The relationship between the width A, the beam spread angle θ, and the beam spread region 30 of the perturbation region PP is illustrated as schematically shown in FIGS. 27A, 27B and 27C, in the 2D-PC SEL according to the first embodiment. More specifically, an example of the width A₁, the beam spread angle θₐ, and the beam spread region 30₁ of the perturbation region PP₁ is illustrated as shown in FIG. 27A, an example of the width A₂, the beam spread angle θ_{b}, and the beam spread region 30₂ of the perturbation region PP₂ is illustrated as shown in FIG. 27B, and an example of the width A₃, the beam spread angle θ_{c}, and the beam spread region 30₃ of the perturbation region PP₂ is illustrated as shown in FIG. 27C. In this case, the size relationship between the widths of the perturbation regions is expressed with A₁<A₂<A₃, and the size of the perturbation region PP₁ is relatively smaller than others, and the size of the perturbation region PP₃ is relatively larger than others. Moreover, θₐ>θ_{b}>θ_{c} is satisfied in the size relationship between the beam spread angles specifying the beam spread regions 30₁, 30₂, 30₃.

In the 2D-PC SEL according to the first embodiment, the size relationship between the resonator regions RP corresponding to FIGS. 27A, 27B and 27C is illustrated as shown in FIG. 28A, and the size relationship of the beam spread angles corresponding thereto is illustrated as shown in FIG. 28B. More specifically, the beam spread angle θ0 becomes small as the size of the resonator region RP becomes large.

### Comparative Example 4

### Square Lattice: Γ Point (Gamma-Point)

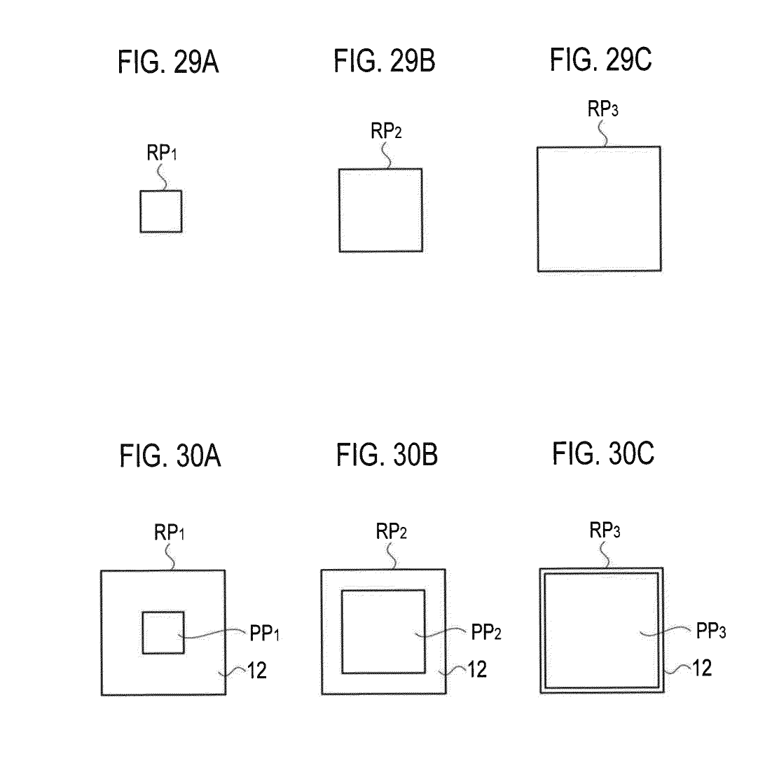

In the 2D-PC SEL according to a comparative example 4, FIG. 29A shows an example of the RP₁, FIG. 29B shows an example of the RP₂, and FIG. 29C shows an example of the RP₃, in a diagram showing a relationship between the sizes of resonator regions RP in the 2D-PC layer applied to the square lattice F-Point (gamma-point) oscillation.

Oh the other hand, in the 2D-PC SEL according to the comparative example 4, FIG. 30A shows an example of RP₁ and PP₁, FIG. 30B shows an example of RP₂ and PP₂, and FIG. 30C shows an example of RP₃ and PP₃, in a diagram showing a relationship between the size of the resonator region RP and the size of the perturbation region PP in the 2D-PC layer applied to the X-point oscillation, for example.

The oscillation of the 2D-PC SEL requires a resonator region having a fixed area or more. Therefore, if the beam spread angle θ is enlarged in the case of the square lattice Γ-point (gamma-point) oscillation according to the comparative example 4, the resonator region RP_{A} required for an oscillation cannot be ensured. More specifically, since the 2D-PC SEL according to the comparative example 4 uses the square lattice Γ-point (gamma-point) oscillation, the size of the resonator region RP is equal to the size of the perturbation region PP in that condition. Accordingly, if the size of the resonator region RP is reduced in order to enlarge the beam spread angle θ, it becomes impossible to oscillate in the range of RP<RP_{A} in the size relationship between the resonator regions RP since the resonator region RP_{A} required for the oscillation cannot not be ensured, as shown in FIG. 28A.

### Modified Example

In to the 2D-PC SEL according to the second embodiment, there may be coexisted the arrangement structure of the lattice point for forming resonant-state 12A and the perturbation lattice point 12P, and the arrangement structure of only the lattice point for forming resonant-state 12A.

More specifically, the 2D-PC SEL according to an modified example of the second embodiment includes: a PC layer 12; a resonator region RP periodically arranged in the PC layer 12, and configured so that PC layer 12 a light wave at a band edge in photonic band structure is diffracted in the plane of the PC layer 12; and a perturbation region PP periodically arranged in the PC layer 12, and configured so that the light wave at the band edge of the photonic band structure in the PC layer 12 is diffracted in the plane of the PC layer 12, and diffracted in a direction normal to the surface of the PC layer 12, wherein the perturbation region PP has two types of lattice points including a first lattice point 12A and a second lattice point 12P, and the configurations of the adjacent first lattice point 12A and second lattice point 12P are different from each other.

Moreover, the shape of the first lattice point 12A and the shape of the second lattice point 12P may be different from each other.

Moreover, the size of the first lattice point 12A and the size of the second lattice point 12P may be different from each other.

Moreover, the shape of the first lattice point 12A and the shape of the second lattice point 12P are the same, but the arrangement directions thereof may be different from each other.

Moreover, the first lattice point 12A and the second lattice point 12P may be provided with any one of a polygonal shape, a circular shape, an ellipse shape, or an oval shape. The polygonal shape includes a triangle, a square, a four-square, a rectangle, etc.

The 2D-PC SEL according to a modified example of the second embodiment, the size of the perturbation region PP is varied while continuing the size of the resonator region RP, thereby adjusting the size and the shape of the light emitting surface of laser beam.

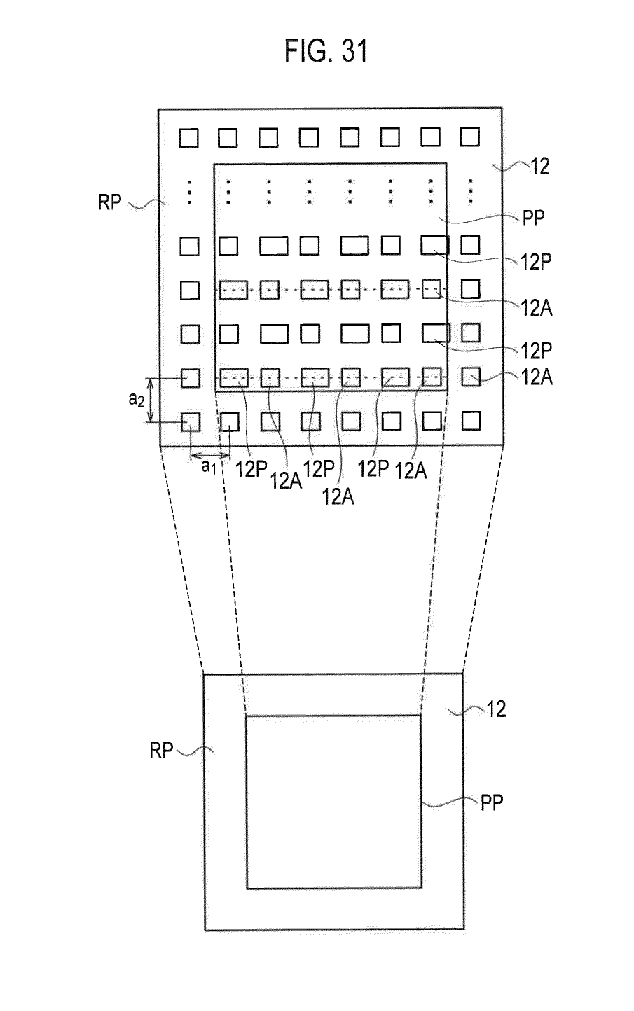

In the 2D-PC SEL according to the modified example of the second embodiment, FIG. 31 shows an example of arrangement of the lattice point for forming resonant-state 12A and the perturbation lattice point 12P in the resonator region RP and the perturbation region PP in the 2D-PC layer 12 applied to the M-point oscillation.

Only the lattice point for forming resonant-state 12A is arranged in the rectangular lattice having the lattice constants (a₁, a₂) in the resonator region RP.

In the perturbation region PP, the adjacent lattice point for forming resonant-state 12A and perturbation lattice point 12P are arranged so as to have different shapes from each other, in the rectangular lattice having the lattice constants (a₁, a₂), in the same manner as FIG. 9A. More specifically, the hole shape of the lattice point for forming resonant-state 12A is a four-square, and the hole shape of the perturbation lattice point 12P is a rectangle. The lattice point for forming resonant-state 12A and the perturbation lattice point 12P diffract the light waves at the M-point band edge in the photonic band structure of the 2D-PC layer 12, in the same manner as shown in FIG. 9A. The lattice point for forming resonant-state 12A is arranged in the rectangular lattice having the lattice constants (a₁, a₂) of the rectangular lattice. Moreover, as a result of applying the periodic perturbation to a part of the lattice point for forming resonant-state 12A to form the perturbation lattice point 12P, the perturbation lattice point 12P is arranged in the face-centered square lattice having the lattice constant (2a₁, 2a₂) twice the lattice constants (a₁, a₂) of the rectangular lattice.

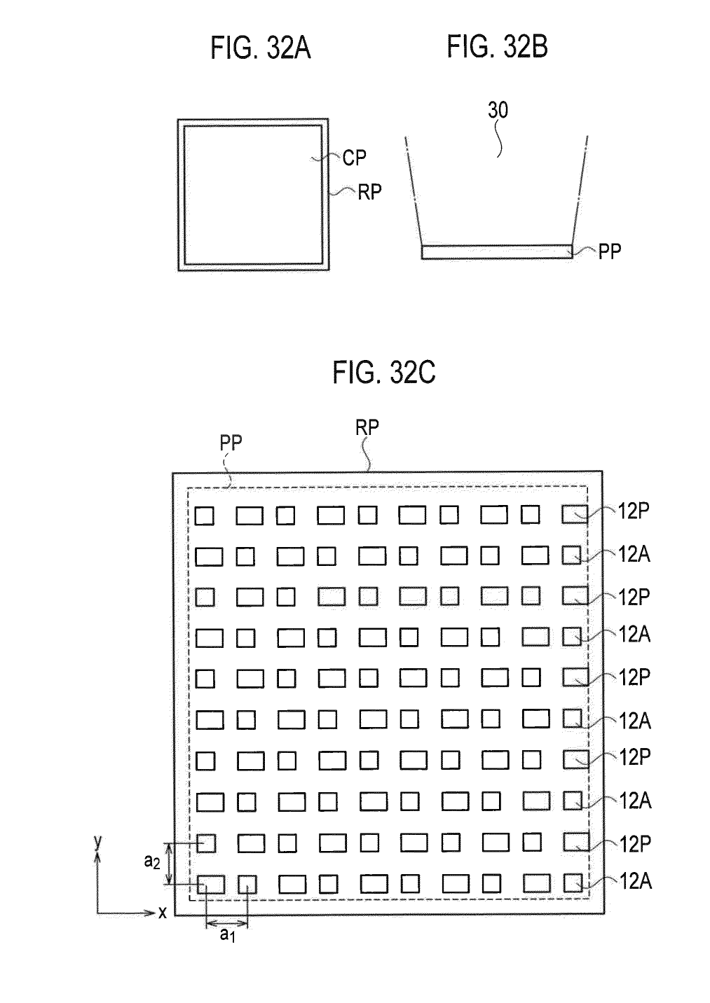

In the 2D-PC SEL according to the modified example of the second embodiment, FIG. 32A shows an NFP in the case of the size of the resonator region RP and the size of the perturbation region PP in the 2D-PC layer 12 applied to the M-point oscillation are nearly equal to each other, FIG. 32B shows the beam spread region 30 from the perturbation region PP, and FIG. 32C shows an example of arrangement of the lattice point for forming resonant-state 12A and the perturbation lattice point 12P in the resonator region RP and the perturbation region PP corresponding to FIG. 32A. The configuration in the perturbation region PP is the same as that shown in FIG. 31.

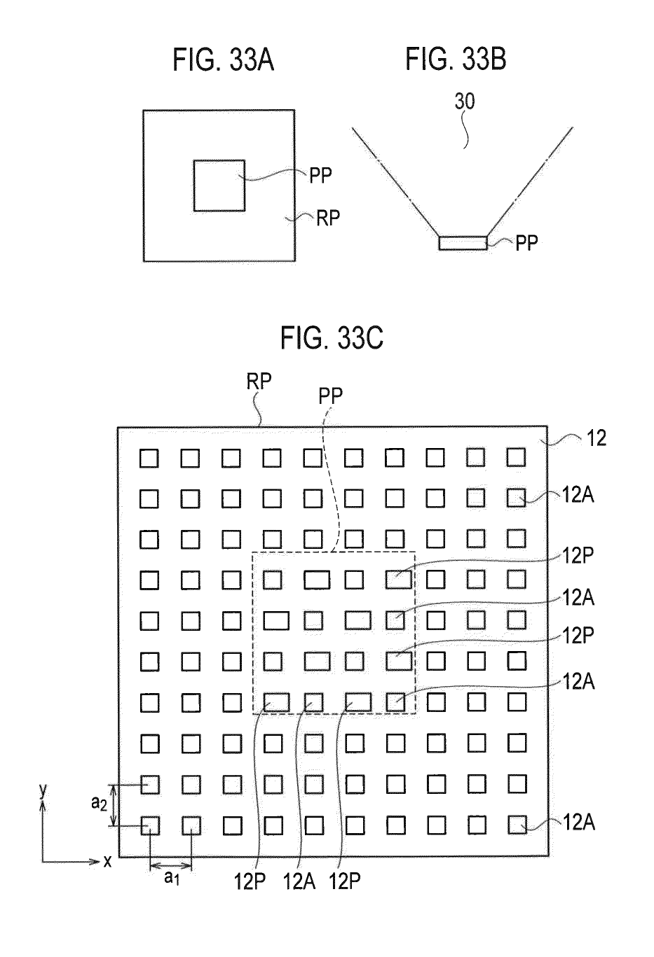

In the 2D-PC SEL according to the modified example of the second embodiment, FIG. 33A shows an NFP in the case of the size of the resonator region RP and the size of the perturbation region PP in the 2D-PC layer 12 applied to the M-point oscillation are different from each other, FIG. 33B shows the beam spread region 30 from the perturbation region PP, and FIG. 33C shows an example of arrangement of the lattice point for forming resonant-state 12A and the perturbation lattice point 12P in the resonator region RP and the perturbation region PP corresponding to FIG. 33A. The configuration in the perturbation region PP is the same as that shown in FIG. 31.

In the 2D-PC SEL according to the modified example of the second embodiment, the resonator region RP and the perturbation region PP can be designed separately from each other.

According to the modified example of the second embodiment, there can be provided the 2D-PC SEL which can vertically emit laser beams with simplified structure, in the non-radiative resonator structure, e.g. the M-point resonator.

Furthermore, the 2D-PC SEL according to the modified example of the second embodiment, the perturbation region PP is varied while continuing the size of the resonator region RP, and thereby the beam emitting angle and the beam spread angle of the laser beam can be adjusted, while continuing the stable oscillation.

### (Example of Generation of Other Various Beams)

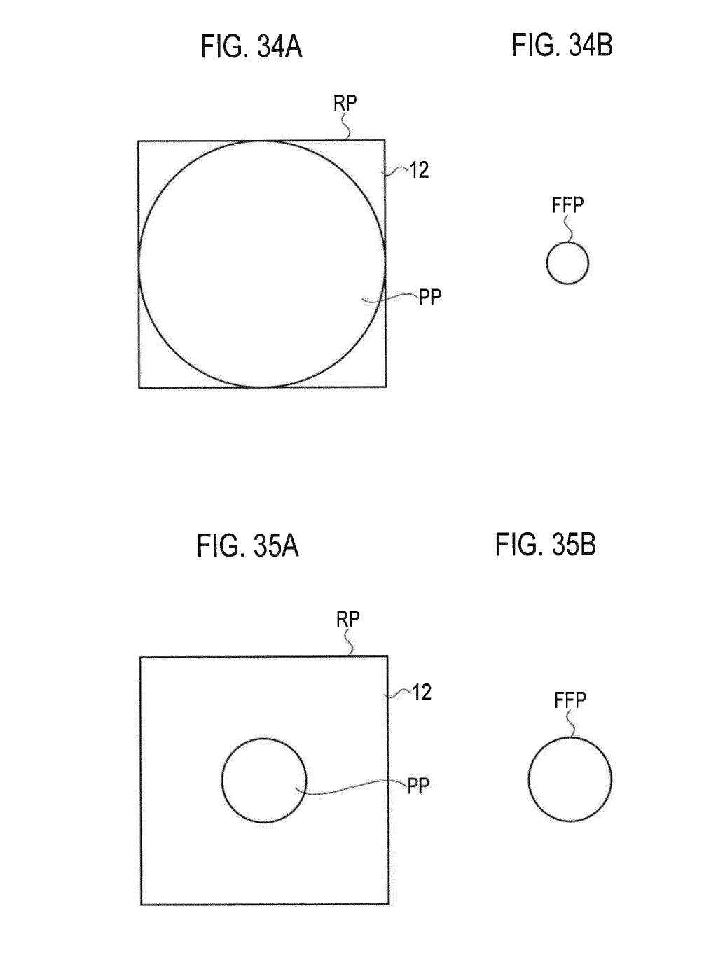

In the 2D-PC SEL according to the modified example of the second embodiment, FIG. 34A shows an NFP in the case where a relatively large circular perturbation region PP is arranged in the resonator region RP of the 2D-PC layer 12 applied to the M-point oscillation, and FIG. 34B shows the FFP corresponding to FIG. 34A.

Moreover, FIG. 35A shows an NFP in the case where a relatively small circular perturbation region PP is arranged in the resonator region RP, and FIG. 35B shows an FFP corresponding to FIG. 35A.

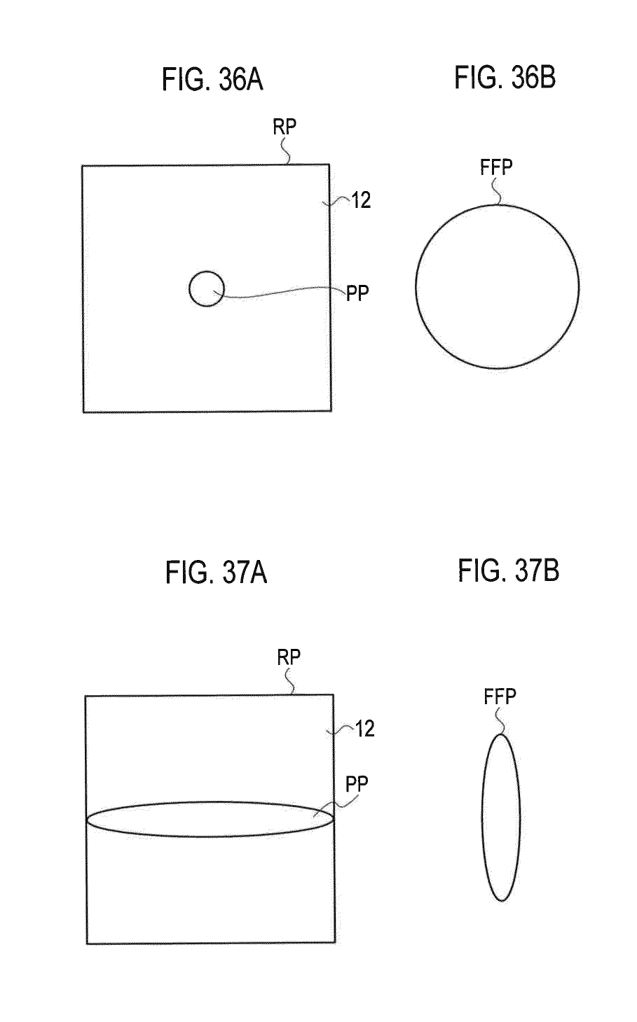

Moreover, FIG. 36A shows an NFP in the case where a relatively micro circular perturbation region PP is arranged in the resonator region RP, and FIG. 36B shows an FFP corresponding to FIG. 36A.

Moreover, FIG. 37A shows an NFP in the case where a relatively large oval-shaped perturbation region PP is arranged in the resonator region RP, and FIG. 37B shows an FFP corresponding to FIG. 37A.

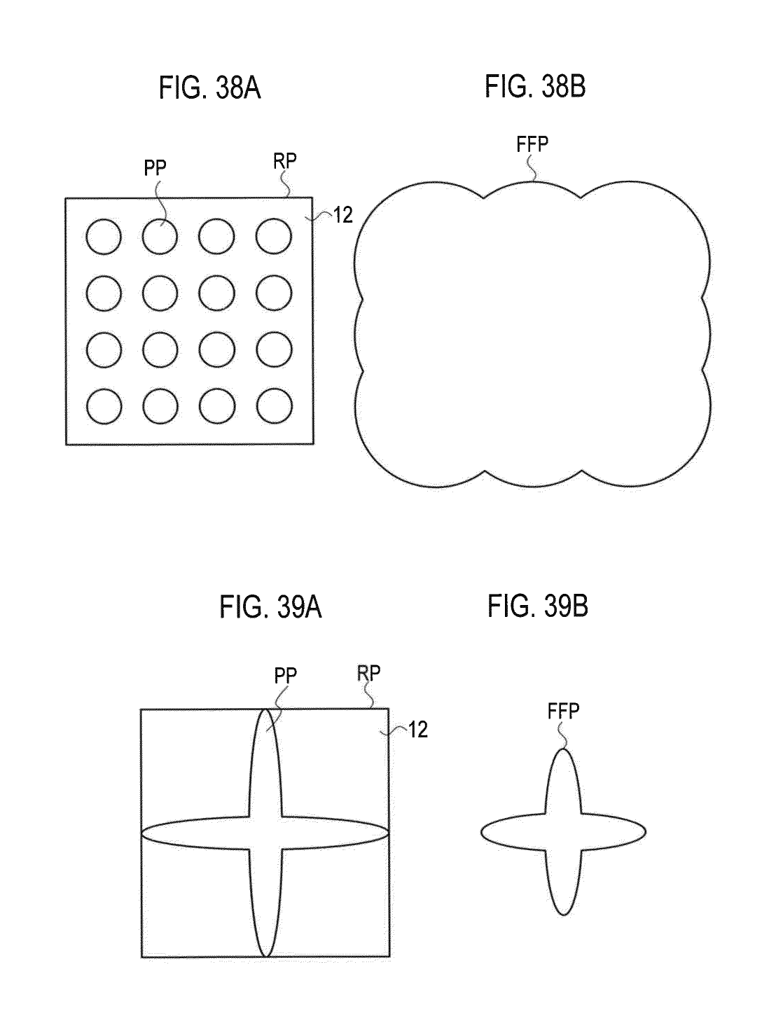

Moreover, FIG. 38A shows an NFP in the case where a plurality of relatively small circular perturbations region PP is arranged in the resonator region RP, and FIG. 38B shows an FFP corresponding to FIG. 38A.

Moreover, FIG. 39A shows an NFP in the case where two oval-shaped perturbation regions PP perpendicularly intersecting with each other are arranged in the resonator region RP, and FIG. 39B shows an FFP corresponding to FIG. 39A.

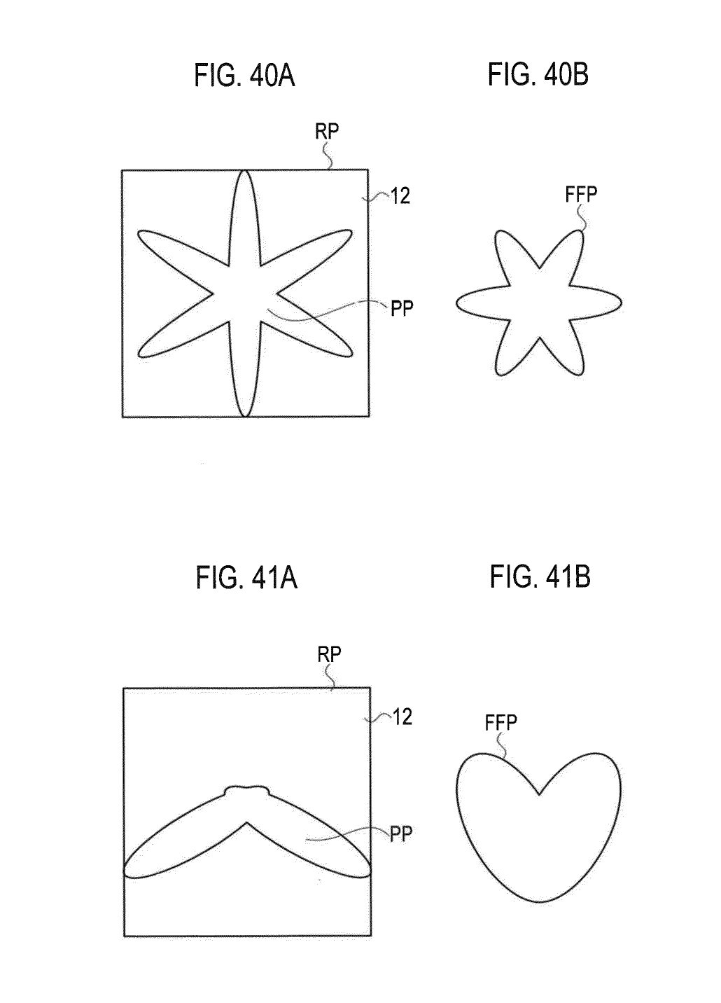

Moreover, FIG. 40A shows an NFP in the case where three oval-shaped perturbation regions PP intersecting at 60 degrees with each other are arranged in the resonator region RP, and FIG. 40B shows an FFP corresponding to FIG. 40A.

Moreover, FIG. 41A shows an NFP in the case where two oval-shaped perturbation regions PP intersecting at 120 degrees with each other are arranged in the resonator region RP, and FIG. 41B shows an FFP corresponding to FIG. 41A.

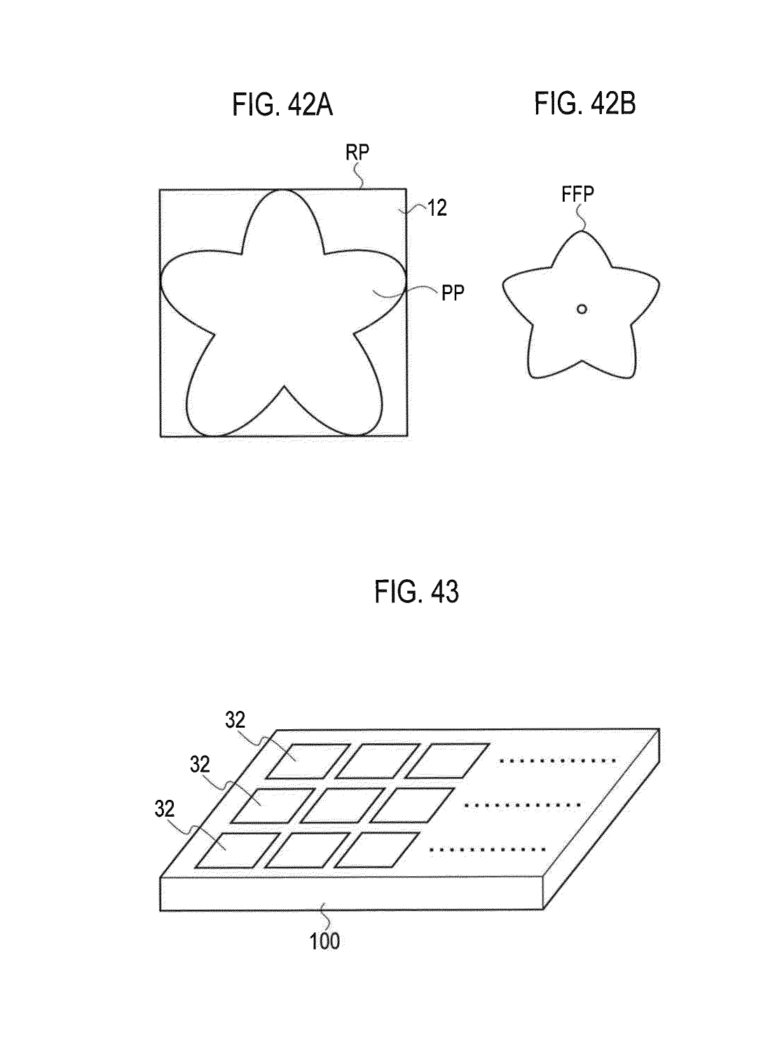

Moreover, FIG. 42A shows an NFP in the case where five oval-shaped perturbation regions PP intersecting at 72 degrees with each other are arranged in the resonator region RP, and FIG. 42B shows an FFP corresponding to FIG. 42A.

In the 2D-PC SEL according to the modified example of the second embodiment, it is possible to adjust the size and the shape of the light emitting surface of laser beams by relatively varying the size of the perturbation region PP, while maintaining the size of the oscillation region, in the oscillation of the M-point band edge in the photonic band structure, as shown in FIGS. 34-42. As an example of the size of NFP, various sizes of the NFP, e.g., several tens of μm square, several hundred of μm square, 1 mm square, can be formed, and the FFP corresponding thereto can also be formed in the same manner as the NFP.

According to the 2D-PC SEL according to the modified example of the second embodiment, since the beam spread angle θ and the shape of laser beam are determined with the size and the shape of the light emitting surface of laser beam, the beam spread angle and the shape of laser beam can be controlled. As the periodic structure for optical amplification is maintained, the oscillation can be performed even if varying the size and the shape of the perturbation region PP.

Since the beam spread angle θ and the shape of the laser beam are determined with the size and the shape of the light emitting surface, when extending the beam spread angle θ0 of laser beam, for example, only the size of the perturbation region PP may be made small relatively, while the size of the resonator region RP of optical amplification is maintained in that condition. Moreover, when the shape of laser beam is made into a rectangle, only the shape of perturbation region PP may also be made into a rectangle.

### Third Embodiment

### (Two-Dimensional Cell Array)

FIG. 43 shows a structural example of two-dimensional cell array for achieving high power output, in a 2D-PC SEL according to an third embodiment. More specifically, cells 32 of the 2D-PC SEL according to the first and second embodiments may be two-dimensionally arranged on a substrate 100, thereby forming two-dimensional cell array. In an example that twenty-one cells are two-dimensionally arranged, thereby forming two-dimensional cell array, a 2D-PC SEL having high output power equal to or greater than 35 W with a current value approximately 50 A can be obtained in 1-kHz and 50-ns pulse driving.

In the example shown in FIG. 43, a cell having different area ratio between the perturbation region PP and the resonator region RP may be arranged in each cell 32. A plurality of the cells 32 of which the area ratios between the perturbation PP and the resonator region RP are different from each other are arranged on the same substrate 100 to be selectively driven, and thereby there can be provided a high-output multifunctional 2D-PC surface light emission laser array which can control the beam spread angle and the shape of laser beam.

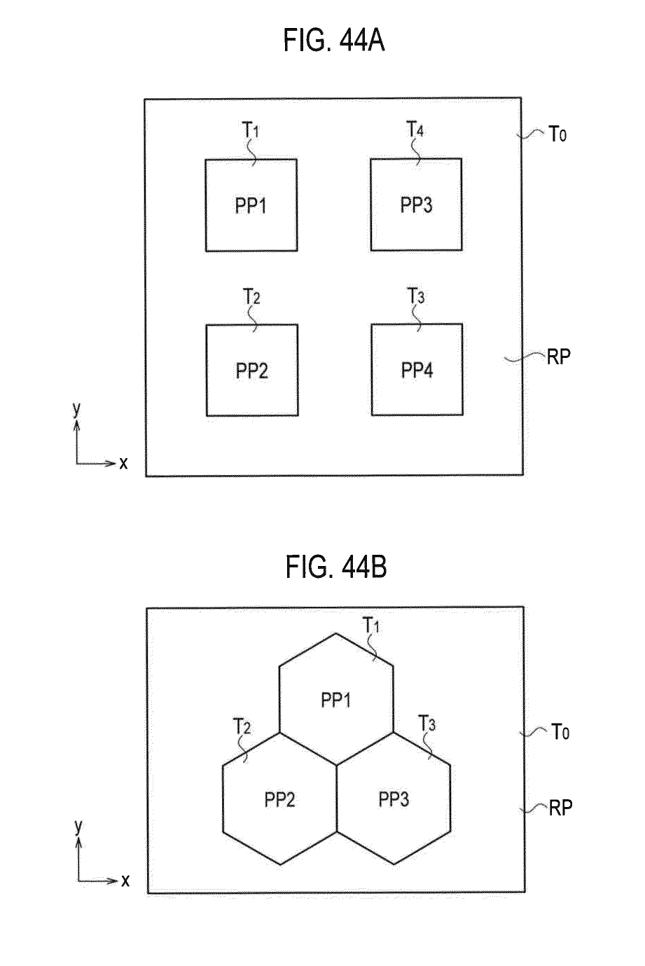

In the 2D-PC SEL according to the third embodiment, FIG. 44A shows a two-dimensional cell arrayed structural example that a basic pattern Tₒ of the lattice point for forming resonant-state is arranged in a 2D-PC layer on a first cladding layer, and perturbation patterns T₁, T₂, T₃, T₄ of rectangular-shaped perturbation regions PP₁, PP₂, PP₃, PP₄ are arranged in the 2D-PC layer. FIG. 44B shows a two-dimensional cell arrayed structural example that the basic pattern T₀ of the lattice point for forming resonant-state is arranged in the 2D-PC layer on the first cladding layer, and the perturbation patterns T₁, T₂, T₃, T₄ of hexagon-shaped perturbation regions PP₁, PP₂, PP₃, PP₄ are arranged in the 2D-PC layer.

In the example shown in FIGS. 44A and 44B, the plurality of the perturbation patterns are arranged, thereby providing the high-output multifunctional 2D-PC surface light emission laser array which can control the beam spread angle and the shape of laser beam.

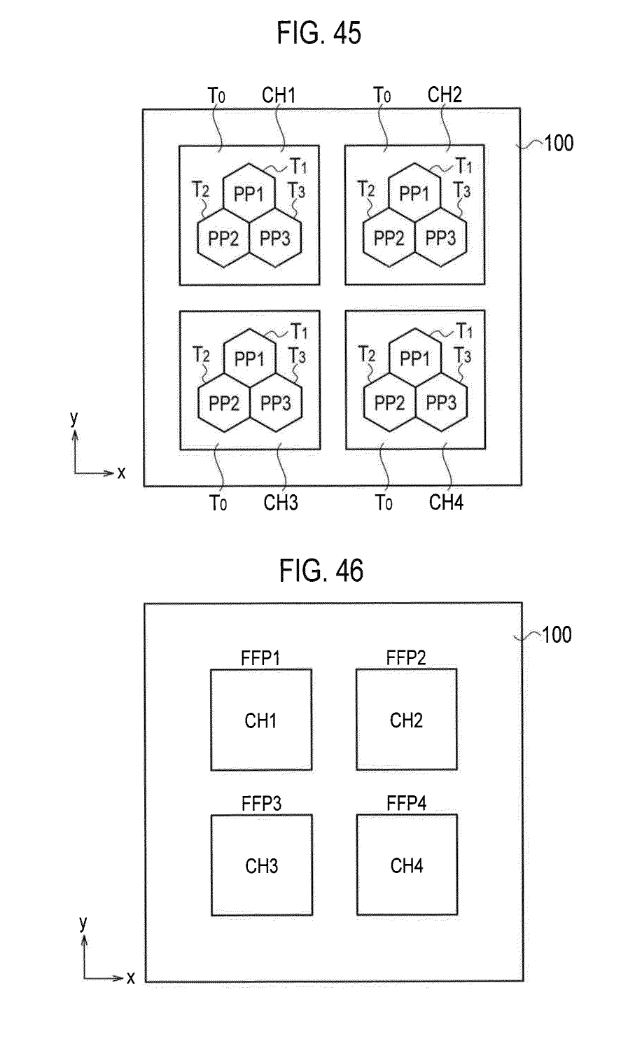

In the 2D-PC SEL according to the third embodiment, a two-dimensional cell arrayed structural example that a plurality of chips CH1, CH2, CH3, CH4 each having the configuration shown in FIG. 44B are arranged on the same substrate 100 is illustrated as shown in FIG. 45.

In the example shown in FIG. 45, the plurality of the chips CH1, CH2, CH3, CH4 which have a plurality of perturbation patterns T₁, T₂, T₃ are respectively arranged on the same substrate 100 to be selectively driven, thereby providing the high-output multifunctional 2D-PC surface light emission laser array which can control the beam spread angle and the shape of laser beam. Moreover, in the 2D-PC SEL according to the third embodiment, a two-dimensional cell arrayed structural example that the plurality of the chips CH1, CH2, CH3, CH4 of which FFPs (FFP1, FFP2, FFP3, FFP4) are different from each other are arranged on the same substrate 100 is illustrated as shown in FIG. 46.

In the example shown in FIG. 46, the plurality of the chips CH1, CH2, CH3, CH4 of which the FFPs (FFP1, FFP2, FFP3, FFP4) are different from each other are arranged on the same substrate 100 to be selectively driven, and thereby providing the high-output multifunctional 2D-PC surface light emission laser array which can control the beam spread angle and the shape of laser beam.

As mentioned-above, according to the embodiments, there can be provided the 2D-PC SEL which can vertically emit laser beams with simplified structure, in the non-radiative resonator structure, e.g. the M-point resonator.

### Other Embodiments

The first to third embodiments have been described herein, as a disclosure including associated description and drawings to be construed as illustrative, not restrictive. This disclosure makes clear a variety of alternative embodiments, working examples, and operational techniques for those skilled in the art.

Such being the case, the embodiments cover a variety of embodiments, whether described or not.

What is claimed is:

1. A two dimensional photonic crystal surface emitting laser comprising:
a photonic crystal layer; and
a lattice point for forming resonant-state arranged in the photonic crystal layer, the lattice point for forming resonant-state configured so that a light wave at a band edge in photonic band structure in the photonic crystal layer is diffracted in a plane of the photonic crystal layer, and is diffracted in a direction normal to the surface of the photonic crystal layer, wherein
the lattice point for forming resonant-state has two types of lattice points including a first lattice point and a second lattice point, and the adjacent first lattice point and second lattice point are different from each other.

2. The two dimensional photonic crystal surface emitting laser according to claim 1, wherein
a shape of the first lattice point and a shape of the second lattice point are different from each other.

3. The two dimensional photonic crystal surface emitting laser according to claim 1, wherein
a size of the first lattice point and a size of the second lattice point are different from each other.

4. The two dimensional photonic crystal surface emitting laser according to claim 1, wherein
a hole depth of the first lattice point and a hole depth of the second lattice point are different from each other.

5. The two dimensional photonic crystal surface emitting laser according to claim 1, wherein
a refractive index of the first lattice point and a refractive index of the second lattice point are different from each other.

6. The two dimensional photonic crystal surface emitting laser according to claim 1, wherein
a shape of the first lattice point and a shape of the second lattice point are the same, but an arrangement direction of the first lattice point and an arrangement direction of the second lattice point are different from each other.

7. The two dimensional photonic crystal surface emitting laser according to claim 1, wherein
the lattice point for forming resonant-state is arranged in any one selected from the group consisting of a square lattice, a rectangular lattice, a face-centered rectangle lattice, and a triangular lattice.

8. The two dimensional photonic crystal surface emitting laser according to claim 1, wherein
the lattice point for forming resonant-state is arranged in a square lattice or a rectangular lattice, and can diffract the light wave at a Γ point, an X point, or an M point in the photonic band structure of the photonic crystal layer in the direction normal to the surface of the photonic crystal layer.

9. The two dimensional photonic crystal surface emitting laser according to claim 1, wherein
the lattice point for forming resonant-state is arranged in a face-centered rectangle lattice or a triangular lattice, and can diffract the light wave at a Γ point, an X point, or an J point in the photonic band structure of the photonic crystal layer in the direction normal to the surface of the photonic crystal layer.

10. The two dimensional photonic crystal surface emitting laser according to claim 1, further comprising:
a substrate;
a first cladding layer disposed on the substrate;
a second cladding layer disposed on the first cladding layer; and
an active layer inserted between the first cladding layer and the second cladding layer.

11. The two dimensional photonic crystal surface emitting laser according to claim 10, wherein
the photonic crystal layer is inserted between the first cladding layer and the second cladding layer so as to be adjacent to the active layer 1 in a direction normal to the surface of the active layer.

12. The two dimensional photonic crystal surface emitting laser according to claim 10, wherein
the photonic crystal layer is inserted between the first cladding layer and the active layer.

13. The two dimensional photonic crystal surface emitting laser according to claim 10, wherein
the photonic crystal layer is inserted between the first cladding layer and the active layer.

14. The two dimensional photonic crystal surface emitting laser according to claim 1, wherein
the first lattice point and the second lattice point are provided with any one of a polygonal shape, a circular shape, an ellipse shape, or an oval shape.

15. A two dimensional photonic crystal surface emitting laser comprising:
a photonic crystal layer;
a lattice point for forming resonant-state periodically arranged in the photonic crystal layer, the lattice point for forming resonant-state configured so that a light wave at a band edge of photonic band structure in the photonic crystal layer is diffracted in a plane of the photonic crystal layer; and
a perturbation lattice point periodically arranged in the photonic crystal layer, the perturbation lattice point configured so that the light wave at the band edge of the photonic band structure in the photonic crystal layer is diffracted in the plane of the photonic crystal layer, and is diffracted in a direction normal to the surface of the photonic crystal layer, wherein
perturbation for diffracting the light wave in the direction normal to the surface of the photonic crystal layer is applied to a part of the lattice point for forming resonant-state, and thereby the perturbation lattice point is formed.

16. The two dimensional photonic crystal surface emitting laser according to claim 15, wherein
the lattice point for forming resonant-state and the perturbation lattice point are arranged in any one selected from the group consisting of a square lattice, a rectangular lattice, a face-centered rectangle lattice, and a triangular lattice.

17. The two dimensional photonic crystal surface emitting laser according to claim 15, wherein
the lattice point for forming resonant-state and the perturbation lattice point are arranged in a square lattice or a rectangular lattice, and can diffract the light wave at a Γ point, an X point, or an M point in the photonic band structure of the photonic crystal layer in the direction normal to the surface of the photonic crystal layer.

18. The two dimensional photonic crystal surface emitting laser according to claim 15, wherein
the lattice point for forming resonant-state and the perturbation lattice point are arranged in a face-centered rectangle lattice or a triangular lattice, and can diffract the light wave at a Γ point, an X point, or an J point in the photonic band structure of the photonic crystal layer in the direction normal to the surface of the photonic crystal layer.

19. A two dimensional photonic crystal surface emitting laser comprising:
a photonic crystal layer;
a resonator region periodically arranged in the photonic crystal layer, the resonator region configured so that a light wave at a band edge of photonic band structure in the photonic crystal layer is diffracted in a plane of the photonic crystal layer; and
a perturbation region periodically arranged in the photonic crystal layer, the perturbation region configured so that the light wave at the band edge of the photonic band structure in the photonic crystal layer is diffracted in the plane of the photonic crystal layer, and is diffracted in a direction normal to the surface of the photonic crystal layer, wherein
the perturbation region has two types of lattice points including a first lattice point and a second lattice point, and the adjacent first lattice point and second lattice point are different from each other.

20. The two dimensional photonic crystal surface emitting laser according to claim 19, wherein
a shape of the first lattice point and a shape of the second lattice point are different from each other.

21. The two dimensional photonic crystal surface emitting laser according to claim 19, wherein
a size of the first lattice point and a size of the second lattice point are different from each other.

22. The two dimensional photonic crystal surface emitting laser according to claim 19, wherein
a shape of the first lattice point and a shape of the second lattice point are the same, but an arrangement direction of the first lattice point and an arrangement direction of the second lattice point are different from each other.

23. The two dimensional photonic crystal surface emitting laser according to claim 19, wherein
a size of the perturbation region is varied while continuing a size of the resonator region, thereby adjusting the size and the shape of a light emitting surface of laser beam.

24. The two dimensional photonic crystal surface emitting laser according to claim 19, wherein
the first lattice point and the second lattice point are provided with any one of a polygonal shape, a circular shape, an ellipse shape, or an oval shape.

25. The two dimensional photonic crystal surface emitting laser according to claim 1, wherein
cells of the 2D-PC surface emitting laser are two-dimensionally arranged, thereby forming a two-dimensional cell array.
